(19) United States
(12) Patent Application Publication
(10) Pub. No.: US 2026/0239795 A1
(43) Pub. Date: Aug. 13, 2026

(54) LIGHT EMITTING DEVICE AND IMAGE DISPLAY DEVICE

(71) Applicant: SONY SEMICONDUCTOR SOLUTIONS CORPORATION, Kanagawa (JP)

(72) Inventor: Hiroyuki KASHIHARA, Kanagawa (JP)

(73) Assignee: SONY SEMICONDUCTOR SOLUTIONS CORPORATION, Kanagawa (JP)

(21) Appl. No.: 19/155,643

(22) PCT Filed: Feb. 2, 2024
(86) PCT No.: PCT/JP2024/003549

§ 371 Date: Aug. 12, 2025

(30) Foreign Application Priority Data
Feb. 20, 2023 (JP) 2023-024684

(51) Int. Cl. H10H 29/49; H10H 29/01

(52) U.S. Cl. CPC H10H 29/49; H10H 29/011; H10H 29/012

(57) ABSTRACT

A light emitting device according to an embodiment of the present disclosure includes: a driving circuit substrate; an element substrate that has a first surface opposed to the driving circuit substrate and a second surface serving as a light exit surface on a side opposite to the first surface, that includes a pixel array section including a plurality of light emitting elements arranged in an array form, and that is joined to the driving circuit substrate through hybrid bonding; and a mounting connection terminal and an external connection terminal that are electrically coupled to the driving circuit substrate outside the pixel array section and that are closer to the element substrate than a joint surface between the driving circuit substrate and the element substrate.

### TECHNICAL FIELD

The present disclosure relates to a light-emitting device and an image display device provided with the same.

### BACKGROUND ART

For example, Patent Literature 1 discloses an image display device in which a nitride semiconductor layer constituting an LED and a driving circuit substrate are laminated.

### CITATION LIST

### Patent Literature

Patent Literature 1: Japanese Unexamined Patent Application Publication No. 2019-129226

### SUMMARY OF THE INVENTION

Meanwhile, with regard to the image display device in which a nitride semiconductor layer constituting an LED and a driving circuit substrate are laminated, it has been desired to improve reduction in production yield due to connection failure during mounting.

It is desirable to provide a light emitting device and an image display device that make it possible to improve production yield.

A light emitting device according to an embodiment of the present disclosure includes: a driving circuit substrate; an element substrate that has a first surface opposed to the driving circuit substrate and a second surface serving as a light exit surface on a side opposite to the first surface, that includes a pixel array section including a plurality of light emitting elements arranged in an array form, and that is joined to the driving circuit substrate through hybrid bonding; and a mounting connection terminal and an external connection terminal that are electrically coupled to the driving circuit substrate outside the pixel array section and that are closer to the element substrate than a joint surface between the driving circuit substrate and the element substrate.

An image display device according to an embodiment of the present disclosure includes a light emitting device. As the light emitting device, the image display device includes the above-described light emitting device according to the embodiment of the present disclosure.

The light emitting device and the image display device according to the embodiments of the present disclosure include the mounting connection terminal and the external connection terminal that are closer to the element substrate than a joint surface between the driving circuit substrate and the element substrate. This makes it easier to couple to an external power source, functional element mounted on the light emitting device, and the like.

### BRIEF DESCRIPTION OF THE DRAWINGS

FIG. 1 is a schematic cross-sectional view illustrating an example of a configuration of a light emitting device according to an embodiment of the present disclosure.

FIG. 2 is a schematic diagram illustrating an example of a planar configuration of the whole light emitting device illustrated in FIG. 1.

FIG. 3 is a schematic diagram illustrating another example of a planar configuration of the whole light emitting device illustrated in FIG. 1.

FIG. 4 is a schematic diagram illustrating another example of a planar configuration of the whole light emitting device illustrated in FIG. 1.

FIG. 5 is a schematic diagram illustrating another example of a planar configuration of the whole light emitting device illustrated in FIG. 1.

FIG. 6 is a schematic diagram enlarging a portion of the planar configuration of the light emitting device illustrated in FIG. 2 and the like.

FIG. 7A is a schematic cross-sectional view for describing an example of a manufacturing process of the light emitting device illustrated in FIG. 1.

FIG. 7B is a schematic cross-sectional view illustrating a subsequent process after FIG. 7A.

FIG. 7C is a schematic cross-sectional view illustrating a subsequent process after FIG. 7B.

FIG. 7D is a schematic cross-sectional view illustrating a subsequent process after FIG. 7C.

FIG. 7E is a schematic cross-sectional view illustrating a subsequent process after FIG. 7D.

FIG. 7F is a schematic cross-sectional view illustrating a subsequent process after FIG. 7E.

FIG. 7G is a schematic cross-sectional view illustrating a subsequent process after FIG. 7F.

FIG. 7H is a schematic cross-sectional view illustrating a subsequent process after FIG. 7G.

8A is a schematic cross-sectional view illustrating a subsequent process after FIG. 7H.

FIG. 8B is a schematic cross-sectional view illustrating a subsequent process after FIG. 8A.

FIG. 8C is a schematic cross-sectional view illustrating a subsequent process after FIG. 8B.

FIG. 8D is a schematic cross-sectional view illustrating a subsequent process after FIG. 8C.

FIG. 8E is a schematic cross-sectional view illustrating a subsequent process after FIG. 8D.

FIG. 8F is a schematic cross-sectional view illustrating a subsequent process after FIG. 8E.

FIG. 8G is a schematic cross-sectional view illustrating a subsequent process after FIG. 8F.

FIG. 8H is a schematic cross-sectional view illustrating a subsequent process after FIG. 8G.

FIG. 8I is a schematic cross-sectional view illustrating a subsequent process after FIG. 8H.

FIG. 8J is a schematic cross-sectional view illustrating a subsequent process after FIG. 8I.

FIG. 8K is a schematic cross-sectional view illustrating a subsequent process after FIG. 8J.

FIG. 8L is a schematic cross-sectional view illustrating a subsequent process after FIG. 8K.

FIG. 8M is a schematic cross-sectional view illustrating a subsequent process after FIG. 8L.

FIG. 8N is a schematic cross-sectional view illustrating a subsequent process after FIG. 8M.

FIG. 8O is a schematic cross-sectional view illustrating a subsequent process after FIG. 8N.

FIG. 9 is a schematic cross-sectional view illustrating an example of a configuration of a light emitting device according to a first modification of the present disclosure.

FIG. 10 is a schematic cross-sectional view illustrating an example of a configuration of a light emitting device according to a second modification of the present disclosure.

FIG. 11 is a schematic cross-sectional view illustrating another example of the configuration of the light emitting device according to the second modification of the present disclosure.

FIG. 12 is a schematic cross-sectional view illustrating an example of a configuration of a light emitting device according to a third modification of the present disclosure.

FIG. 13 is a schematic cross-sectional view illustrating an example of a configuration of a light emitting device according to a fourth modification of the present disclosure.

FIG. 14 is a schematic cross-sectional view illustrating an example of a configuration of a light emitting device according to a fifth modification of the present disclosure.

FIG. 15 is a schematic cross-sectional view illustrating an example of a configuration of a light emitting device according to a sixth modification of the present disclosure.

FIG. 16 is a schematic cross-sectional view illustrating an example of a configuration of a light emitting device according to a seventh modification of the present disclosure.

FIG. 17 is a schematic cross-sectional view illustrating an example of a configuration of a light emitting device according to an eighth modification of the present disclosure.

FIG. 18 is a schematic cross-sectional view illustrating an example of a configuration of a light emitting device according to a ninth modification of the present disclosure.

FIG. 19 is a schematic cross-sectional view illustrating an example of a configuration of a light emitting device according to a tenth modification of the present disclosure.

FIG. 20 is a schematic cross-sectional view illustrating an example of a configuration of a light emitting device according to an 11th modification of the present disclosure.

FIG. 21 is a schematic diagram enlarging a portion of the planar configuration of the light emitting device according to a 12th modification of the present disclosure.

FIG. 22 is a perspective view illustrating an example of a configuration of an image display device according to an application example of the present disclosure.

FIG. 23 is a schematic diagram illustrating an example of a wiring layout of the image display device illustrated in FIG. 22.

FIG. 24 is a perspective view illustrating an example of a configuration of an image display device according to an application example of the present disclosure.

FIG. 25 is a perspective view illustrating a configuration of a mounting substrate illustrated in FIG. 24.

FIG. 26 is a perspective view illustrating a configuration of a unit substrate illustrated in FIG. 25.

FIG. 27 is a diagram illustrating an example of the image display device according to the application examples of the present disclosure.

### MODES FOR CARRYING OUT THE INVENTION

Next, with reference to drawings, details of embodiments of the present disclosure will be described. The following description is a specific example of the present disclosure, and the present disclosure is not limited to the following embodiments. In addition, the present disclosure is not limited to placements, dimensions, dimensional ratios, and the like of respective structural elements in each diagram. It is to be noted that the description will be given in the following order.
1. Embodiment (example where sapphire substrate is patterned on light exit surface of light emitting element)
1-1. Configuration of Light Emitting Device
1-2. Manufacturing Method of Light Emitting Device
1-3. Actions and Effects
2. Modifications
2-1. First Modification (another example of light emitting device)
2-2. Second Modification (another example of light emitting device)
2-3. Third Modification (another example of light emitting device)
2-4. Fourth Modification (another example of light emitting device)
2-5. Fifth Modification (another example of light emitting device)
2-6. Sixth Modification (another example of light emitting device)
2-7. Seventh Modification (another example of light emitting device)
2-8. Eighth Modification (another example of light emitting device)
2-9. Ninth Modification (another example of light emitting device)
2-10. Tenth Modification (another example of light emitting device)
2-11. 11th Modification (another example of light emitting device)
2-12. 12th Modification (another example of light emitting device)
3. Application Example

### 1. Embodiment

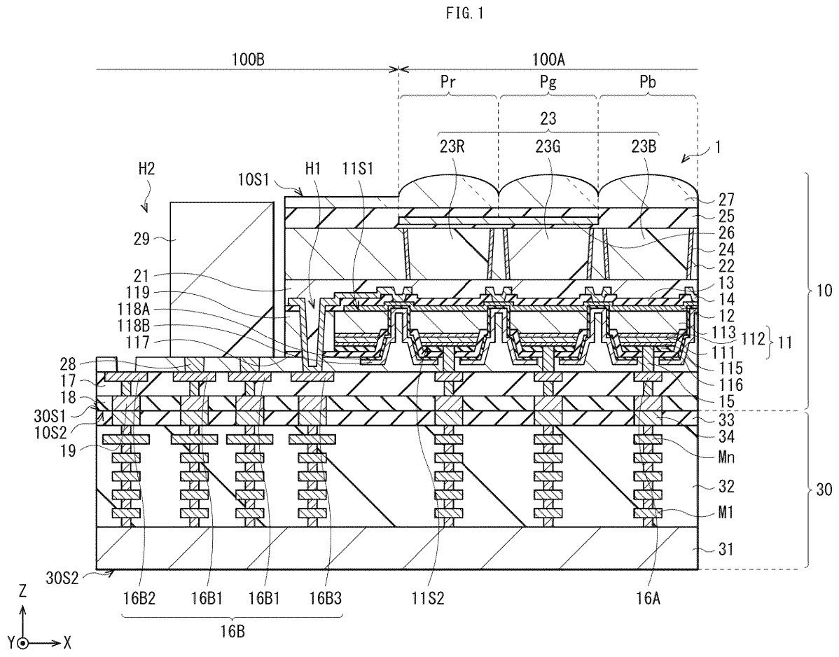

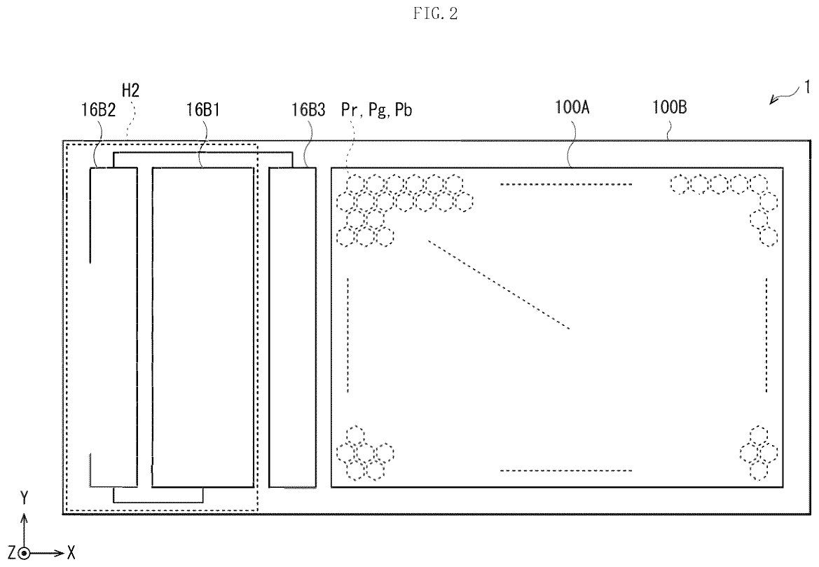

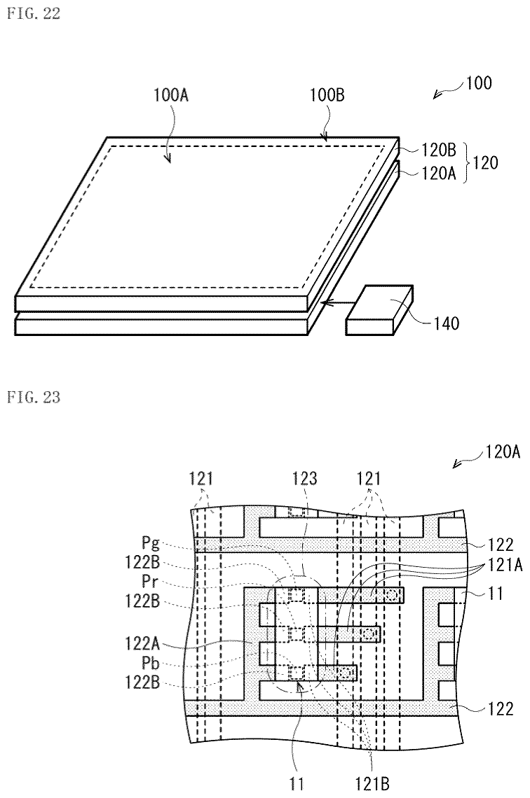

FIG. 1 schematically illustrates an example of a cross-sectional configuration of a light emitting device (light emitting device 1) according to an embodiment of the present disclosure. FIG. 2 to FIG. 5 schematically illustrate examples of a planar configuration of the whole light emitting device 1 illustrated in FIG. 1. The light emitting device 1 is suitably applicable to an image display device (for example, image display device 100, see FIG. 22) which is a so-called LED display.

### 1-1. Configuration of Light Emitting Device

The light emitting device 1 is obtained by joining an element substrate 10 and a driving circuit substrate 30 through hybrid bonding. The element substrate 10 includes a display section 100A and a frame section 100B. The display region 100A includes a plurality of light emitting elements 11 that are two-dimensionally arrayed. The frame section 100B is disposed around the display section 100A. The element substrate 10 has a surface 10S1 and a surface 10S2. The surface 10S1 serves as a light exit surface. The surface 10S2 is on a side opposite to the surface 10S1. The driving circuit substrate 30 is stacked on the surface-10S2 side of the element substrate. The driving circuit substrate 30 has a surface 30S1 and a surface 30S2. The surface 30S1 is opposed to the element substrate 10. The surface 30S2 is on a side opposite to the surface 30S1. The driving circuit substrate 30 is provided with a driving circuit or the like for controlling driving of the plurality of light emitting elements disposed in the display section 100A. The light emitting device 1 includes a mounting connection terminal 16B1 and an external connection terminal 16B2 that are formed in the frame section 100B. On the mounting connection terminal 16B1, a display drive IC (DDIC) 29 is mounted. The external connection terminal 16B2 is coupled to an external power source. According to the present embodiment, the mounting connection terminal 16B1 and the external connection terminal 16B2 are closer to the element substrate 10 than a joint surface between the driving circuit substrate 30 and the element substrate 10.

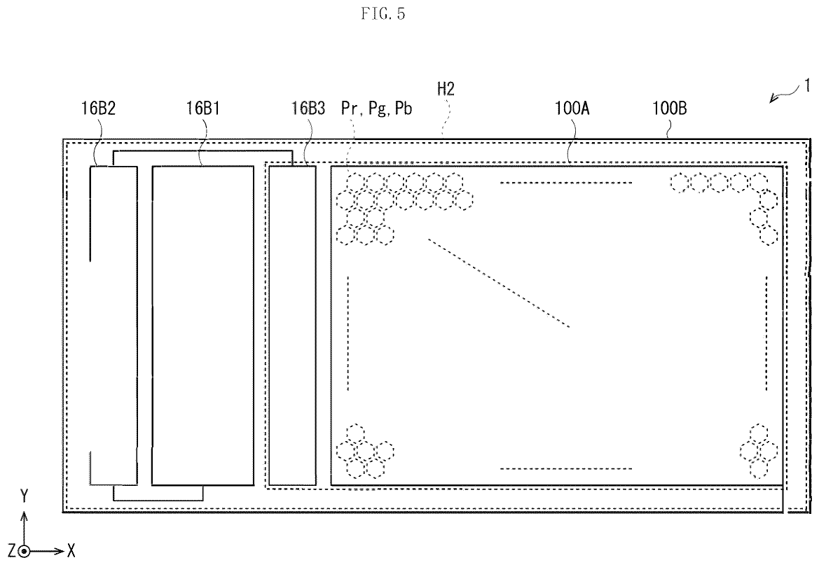

The element substrate 10 includes the plurality of light emitting elements 11 that are obtained by separating a compound semiconductor layer 110 extending in the display section 100A. For example, as illustrated in FIG. 6, the plurality of pixels has a substantially regular hexagonal shape and is disposed in a honeycomb pattern in the display section 100A. On a light-extraction-surface (surface 11S1) side of the plurality of the light emitting elements 11, an electrode layer 12, an insulating layer 13, and an extraction electrode 14 are formed in this order. On a surface 11S2 side of the plurality of the light emitting elements 11, electrode layers 115, insulating layers 116, protection layers 117, an insulating film 118A, and a reflection film 118B are formed. The electrode layer 115, the insulating layer 116, and the protection layer 117 are provided for each element. The insulating film 118A and the reflection film 118B are successive for the plurality of light emitting elements 11. The element substrate 10 further includes an embedding layer 119 and a wiring layer on the driving-circuit-substrate 30 side. The embedding layer 119 embedding the plurality of light emitting elements 11 from the surface 10S2 side. The wiring layer forms a joint surface to be joined to the driving circuit substrate 30. In addition, the element substrate 10 further includes a planarizing layer 21, a partition wall layer 22, and a wavelength conversion layer 23 on the surface 10S1 side. For example, the partition wall layer 22 has an opening 22H for each light emitting element 11, and the wavelength conversion layer 23 is formed inside the opening 22H. In addition, a reflection film 24 is provided between the partition wall layer 22 and the wavelength conversion layer 23. In addition, a protection layer 25 is provided on the light-exit-surface S1 side of the wavelength conversion layer 23, and a wavelength selective layer 26 is provided in the protection layer 25. In addition, an on-chip lens layer 27 is provided on the protection layer 25.

The light emitting element 11 corresponds to a specific example of a “light emitting element” according to an embodiment of the present disclosure. The light emitting element 11 is a solid-state light emitting element that emits light of a predetermined wavelength band from the surface 11S1, such as a light emitting diode (LED) chip. The LED chip represents a chip obtained by cutting a wafer whose crystal has grown, which is not in a package type surrounded by a molding resin or the like. The LED chip is called a micro LED since it has a size of, for example, 0.5 μm or above and 100 μm or less.

The light emitting element 11 includes a first conductivity-type layer 111, an active layer 112, and a second conductivity-type layer 113 that are stacked in this order, and the second conductivity-type layer has an upper surface serving as the surface 11S1.

For example, the first conductivity-type layer 111 is formed by a p-type GaN-based semiconductor material. The active layer 112 has, for example, a multi-quantum-well structure in which InGaN and GaN are alternately stacked, and has a light emitting region therein. From the active layer 112, for example, light in a blue band of 430 nm or more and 500 nm or less is extracted. In addition, light having a wavelength corresponding to, for example, an ultraviolet region (ultraviolet light) may be extracted from the active layer 112. For example, the second conductivity-type layer 113 is formed by an n-type GaN-based semiconductor material. It is to be noted that the conductivity types of the first conductivity-type layer 111 and the second conductivity-type layer 113 are not limited thereto. For example, the first conductivity-type layer 111 may be formed by the n-type GaN-based semiconductor material, and the second conductivity-type layer 113 may be formed by the p-type GaN-based semiconductor material.

The electrode layer 12 serves as a common electrode for the plurality of light emitting elements 11 and is successively formed on the respective surfaces 11S1 of the plurality of light emitting elements 11. The electrode layer 12 is in ohmic contact with the second conductivity-type layer 113. For example, the electrode layer 12 is formed by transparent electrode material such as zinc oxide (ZnO), ITO, indium zinc oxide (IZO), tin oxide (SnO), or TiO.

The insulating layer 13 embeds bumps and dips formed above the plurality of light emitting elements 11. The insulating layer 13 is formed by silicon oxide (SiO), silicon nitride (SiN), or the like, for example.

The extraction electrode 14 applies voltage to the respective second conductivity-type layers 113 of the plurality of light emitting elements 11. For example, the extraction electrode 14 is electrically coupled to the electrode layer 12 via an opening that is made in the insulating layer 13 between the adjacent light emitting elements 11. For example, in the display section 100A, the extraction electrode 14 is successively formed between the adjacent light emitting elements 11 that are disposed in the honeycomb pattern, and extends to a portion of the frame section 100B in such a manner that the extraction electrode 14 avoids the surface 11S1 of the plurality of light emitting elements 11. The extraction electrode 14 formed in the frame section 100B is electrically coupled to a pad connection layer 16B3 via an opening H1 that penetrates the insulating layer 13, the embedding layer 119, and the protection layer 117. The extraction electrode 14 is formed by using a monolayer film, a multilayer film (Ti/Al) of Ti and Al, a multilayer film (Cr/Au) of Cr and Au, or the like. The monolayer film includes palladium (Pd), chromium (Cr), titanium (Ti), aluminium (Al), platinum (Pt), silver (Ag), nickel (Ni), gold (Au), or the like.

The electrode layer 12 and the extraction electrode 14 correspond to a specific example of a “cathode electrode” according to an embodiment of the present disclosure. The pad connection layer 16B3 coupled to the extraction electrode 14 is not electrically coupled to the driving circuit substrate 30. The extraction electrode 14 is routed in the element substrate 10 without passing through the driving circuit substrate 30 and is coupled to the external power source.

The electrode layer 115 is formed on a lower surface (surface 11S2) of the first conductivity-type layer 111 of the light emitting element 11. The electrode layer 115 corresponds to a specific example of an “anode electrode” according to an embodiment of the present disclosure. The electrode layer 115 is in ohmic contact with the first conductivity-type layer 111. For example, the electrode layer 115 is formed by transparent conductive material such as a multilayer film (Ni/Au) of nickel (Ni) and gold (Au), ITO, or the like.

The insulating layer 116 is provided on the electrode layer 115. The insulating layer 116 is formed by silicon oxide (SiO), silicon nitride (SiN), or the like, for example.

On the driving-circuit-substrate 30 side, the light emitting element 11 has a mesa shape including the first conductivity-type layer 111, the active layer 112, and a portion of the second conductivity-type layer 113. The surface 11S2 of the light emitting element 11, and side surfaces of the first conductivity-type layer 111, the active layer 112, and the portion of the second conductivity-type layer 113 that are processed into the mesa shape are covered with the protection layer 117. For example, the protection layer 117 is formed by a monolayer film of silicon oxide (SiO), silicon nitride (SiN), aluminium oxide (Al₂O₃), aluminum nitride, (AlN), or the like, or a stacked film thereof.

In addition, a surface of the protection layer 117 and a side surface of the second conductivity-type layer 113 exposed from the protection layer 117 are covered by a stacked film including the insulating film 118A and the reflection film 118B. The stacked film is successively formed for the plurality of light emitting elements 11. The stacked film has an opening 118H on the surface 11S2 side of the light emitting element 11, and a plug 15 is formed in the opening 118H.

The plugs 15 apply voltages to the respective first conductivity-type layers 111 of the plurality of light emitting elements 11. The plugs 15 are formed by using copper (Cu), aluminium (Al), tungsten (W), silver (Ag), or alloys thereof, for example.

The embedding layer 119 embeds the plurality of light emitting elements 11 and includes the embedding layer 119 that forms a flat stacked surface over the display section 100A and the frame section 100B on the driving-circuit-substrate 30 side. In the frame section 100B, the embedding layer 119 also forms a flat surface successive to the surfaces 11S1 of the plurality of light emitting elements 11. The embedding layer 119 is formed by silicon oxide (SiO), silicon nitride (SiN), or the like, for example.

The driving-circuit-substrate 30 side of the embedding layer 119 is provided with the insulating layer 17. In the insulating layer 17, a plurality of pad connection layers 16B and vias are formed. The plurality of pad connection layers 16B includes a plurality of pad sections 16A provided for the respective light emitting elements 11A in the display section 100A and the pad connection layer 16B3 provided in the frame section 100B. The insulating layer 17 is formed by silicon oxide (SiO), silicon nitride (SiN), or the like, for example. The pad sections 16A, the pad connection layers 16B, and vias are formed by using copper (Cu), tantalum (Ta), cobalt (Co), titanium (Ti), aluminium (Al), tungsten (W), silver (Ag), or alloys thereof, for example. Alternatively, the pad sections 16A, the pad connection layers 16B, and vias may be formed by tantalum nitride (TaN), titanium nitride (TiN), or the like, for example.

In addition, the driving-circuit-substrate 30 side of the insulating layer 17 is provided with an insulating layer 18 and a plurality of pad electrodes 19. The insulating layer 18 forms a joint surface to be joined to the driving circuit substrate 30. The plurality of pad electrodes 19 are embedded in the insulating layer 18. The insulating layer 18 is formed by silicon oxide (SiO), silicon nitride (SiN), or the like, for example. The plurality of pad electrodes 19 bonds the element substrate 10 and the driving circuit substrate 30 electrically and physically. The pad electrodes 19 are formed by using copper (Cu), gold (Au), or the like, for example.

The insulating layer 17 including the plurality of pad sections 16A, pad connection layers 16B, and vias and the insulating layer 18 embedded with the plurality of pad electrodes 19 correspond to the above-described wiring layer, and also corresponds to a specific example of a “first wiring layer” according to an embodiment of the present disclosure. In addition, the plurality of pad electrodes 19 corresponds to a specific example of “first pad electrodes” according to an embodiment of the present disclosure.

The planarizing layer 21 planarizes the light extraction surface (surface 11S1) of the display section 100A including the plurality of light emitting elements 11 arranged in an array form. The planarizing layer 21 is formed by silicon oxide (SiO), silicon nitride (SiN), or the like, for example.

The partition wall layer 22 suppresses occurrence of color mixing due to leakage of light into adjacent RGB sub pixels (red pixels Pr, green pixels Pg, and blue pixels Pb) when applying the light emitting device 1 to the image display device 100. For example, the partition wall layer 22 has a honeycomb structure. Specifically, as illustrated in FIG. 6, the partition wall layer 22 has the substantially regular hexagonal opening 22H for each of the plurality of light emitting elements 11 arranged in the array form, for example. For example, in cross-sectional view, the opening 22H has an inclined surface of less than 90° with respect to a surface 20S2 of the wavelength conversion section 20, the surface 2 0S2 being on a side opposite to a surface 20S1. That is, the partition wall layer 22 has a forward tapered shape among the adjacent color pixels Pr, Pg, and Pb in cross-sectional view. The partition wall layer 22 is preferably formed by using material having a high thermal conductivity and a high electric conductivity. For example, the partition wall layer 22 is formed by using metal material such as copper (Cu), aluminium (Al), gold (Au), nickel (Ni), or platinum (Pt).

The wavelength conversion layer 23 converts light output from the plurality of light emitting elements 11 into desired wavelengths (for example, red (R)/green (G)/blue (B)) and outputs the converted light. The wavelength conversion layer 23 is formed in the opening 22H made above each light emitting element 11. Specifically, the red pixel Pr is provided with a red wavelength conversion layer 23R that converts light output from a light emitting element 11 into red band light (red light), the green pixel Pg is provided with a green wavelength conversion layer 23G that converts light output from a light emitting element 11 into green band light (green light), and the blue pixel Pb is provided with a blue wavelength conversion layer 23B that converts light output from a light emitting element 11 into blue band light (blue light).

It is possible to form the wavelength conversion layers 23R, 23G, and 23B by using respective quantum dots corresponding to the respective colors. Specifically, in a case of obtaining the red light, it is possible to select the quantum dots from among InP, GaInP, InAsP, CdSe, CdZnSe, CdTeSe, CdTe, and the like, for example. In a case of obtaining the green light, it is possible to select the quantum dots from among InP, GaInP, ZnSeTe, ZnTe, CdSe, CdZnSe, CdS, CdSeS, and the like, for example. In a case of obtaining the blue light, it is possible to select the quantum dots from among ZnSe, ZnTe, ZnSeTe, CdSe, CdZnSe, CdS, CdZnS, CdSeS, and the like. It is to be noted that, in a case where a light emitting element 11 outputs the blue light as described above, the blue wavelength conversion layer 23B may be formed by a resin layer having light transparency.

The reflection film 24 is provided on a side surface of the opening 22H for efficiency extracting, from the light extraction surface (surface 22S1) of the wavelength conversion layer 23, the respective color light beams that are output from the light emitting elements 11 and converted by the respective wavelength conversion layers 23R, 23G, and 23B. The reflection film 24 is formed by using metal material having light reflectivity. Examples of the metal material used for forming the reflection film 24 include metals having high reflectance in a visible light region. Specific examples of the material include silver (Ag), aluminium (Al), copper (Cu), gold (Au), platinum (Pt), rhodium (Rh), and alloys thereof.

It is to be noted that the reflection film 24 does not necessarily have to be formed in a case where the partition wall layer 22 is formed by using the above-described metal material having the light reflectivity.

The protection layer 25 for protecting a surface of the light emitting device 1 is formed by silicon oxide (SiO), silicon nitride (SiN), or the like, for example.

The protection layer 25 includes the wavelength selective layer 26 provided over the red pixel Pr and the green pixel Pg. The wavelength selective layer 26 selectively reflects the blue band light (blue light), for example. This makes it possible to improve color purity of the red light extracted from the red pixel Pr and the green light extracted from the green pixel Pg.

The on-chip lens layer 27 is provided to cover the whole display section 100A and the whole frame section 100B. The on-chip lens layer 27 includes light transmissive material. For example, the on-chip lens layer 27 includes a monolayer film containing one selected from inorganic materials such as the group consisting of silicon oxide (SiOx), silicon nitride (SiNx), and silicon oxynitride (SiCN), or alternatively, the on-chip lens layer 27 includes a stacked film containing at least two selected therefrom. Alternatively, the on-chip lens layer 27 may be formed by using organic material.

The frame section 100B has a dug section H2 that penetrates the on-chip lens layer 27, the protection layer 25, the partition wall layer 22, the planarizing layer 21, the insulating layer 13, and the protection layer 117, and that is obtained through digging while leaving a portion of the embedding layer 119. The above-described frame section 100B of the insulating layer 17 includes the mounting connection terminal 16B1 and the external connection terminal 16B2. On the mounting connection terminal 16B1, the display drive IC (DDIC) 29 is mounted. The external connection terminal 16B2 is coupled to the external power source. The mounting connection terminal 16B1 corresponds to a specific example of a “first pad connection layer” according to an embodiment of the present disclosure. The external connection terminal 16B2 corresponds to a specific example of a “second pad connection layer” according to an embodiment of the present disclosure.

For example, the mounting connection terminal 16B1 and the external connection terminal 16B2 are formed in a same layer as the pad connection layer 16B3 coupled to the extraction electrode 14 and the plurality of pad sections 16A electrically coupled to the respective light emitting elements 11 via the plugs 15 in the display section 100A. Openings 119H1 and 119H2 penetrate the remaining embedding layer 119 and are respectively formed above the mounting connection terminal 16B1 and the external connection terminal 16B2. For example, the DDIC 29 is disposed in the dug section H2, and is coupled to the mounting connection terminal 16B1 via a bump 28 formed in the opening 119H1, for example. For example, the external connection terminal 16B2 s coupled to a flexible substrate or a printed wiring board via the opening 119H2.

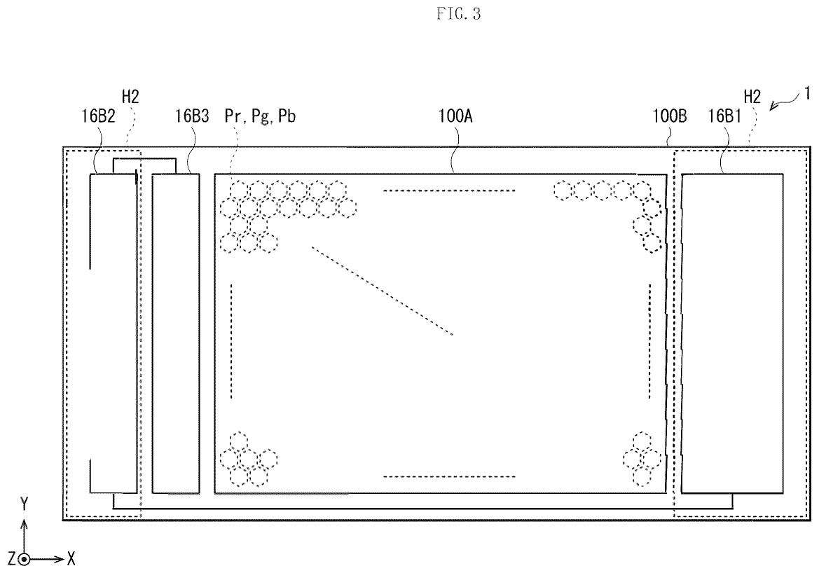

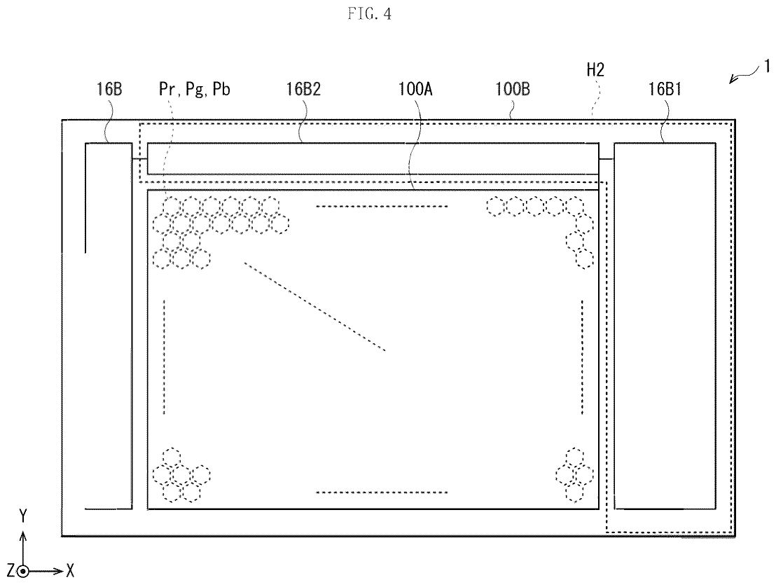

In view of implementation and response speed, it is to be noted that, with regard to the mounting connection terminal 16B1, the external connection terminal 16B2, and the pad connection layer 16B3 that are formed in the frame section 100B, as illustrated in FIG. 2, the pad connection layer 16B3 is preferably disposed near the display section 100A, and the mounting connection terminal 16B1 and the external connection terminal 16B2 are preferably disposed next to the pad connection layer 16B3 in plan view. However, the layout of the display section 100A, the mounting connection terminal 16B1, the external connection terminal 16B2, and the pad connection layer 16B3 is not limited thereto, and they may be disposed as described below. For example, as illustrated in FIG. 3, the mounting connection terminal 16B1 and the external connection terminal 16B2 may be disposed to sandwich the display section 100A and the pad connection layer 16B in plan view. Alternatively, for example, as illustrated in FIG. 4, the mounting connection terminal 16B1, the external connection terminal 16B2, and the pad connection layer 16B3 are disposed along the respective sides of the display section 100A that has a rectangular shape, for example. In addition, FIG. 2 illustrates the example in which the dug section H2 is selectively formed in a region where the mounting connection terminal 16B1 and the external connection terminal 16B2 are formed. However, for example, as illustrated in FIG. 5, the dug section H2 may be formed to surround the display section 100A and the pad connection layer 16B3.

The driving circuit substrate 30 is provided with a driving circuit or the like that controls driving of the plurality of light emitting elements 11 arranged in the display section 100A. For example, the driving circuit substrate 30 includes a support substrate 31, an interlayer insulating layer 32, an insulating layer 33, and pad electrodes 34. The interlayer insulating layer 32 is provided on the support substrate 31 and includes a plurality of wiring layers (for example, wiring M1 to wiring Mn) and vias for electrically coupling wiring layers. The insulating layer 33 forms a joint surface to be joined to the element substrate 10. The pad electrodes 34 are embedded in the insulating layer 33.

The interlayer insulating layer 32 is formed by silicon oxide (SiO), silicon nitride (SiN), or the like, for example.

The wiring layers M1 to Mn and the vias for electrically coupling the respective wiring layers are formed by using copper (Cu), tantalum (Ta), cobalt (Co), titanium (Ti), aluminium (Al), tungsten (W), silver (Ag), or alloys thereof, for example. Alternatively, the wiring layers M1 to Mn and the vias for electrically coupling the respective wiring layers may be formed by tantalum nitride (TaN), titanium nitride (TiN), or the like, for example. The insulating layer 33 is formed by silicon oxide (SiO), silicon nitride (SiN), or the like, for example. The pad electrodes 34 are formed by using copper (Cu), gold (Au), or the like, for example.

### 1-2. Manufacturing Method of Light Emitting Device

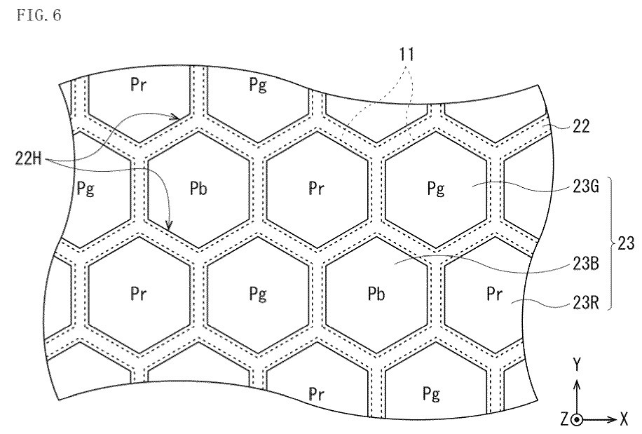

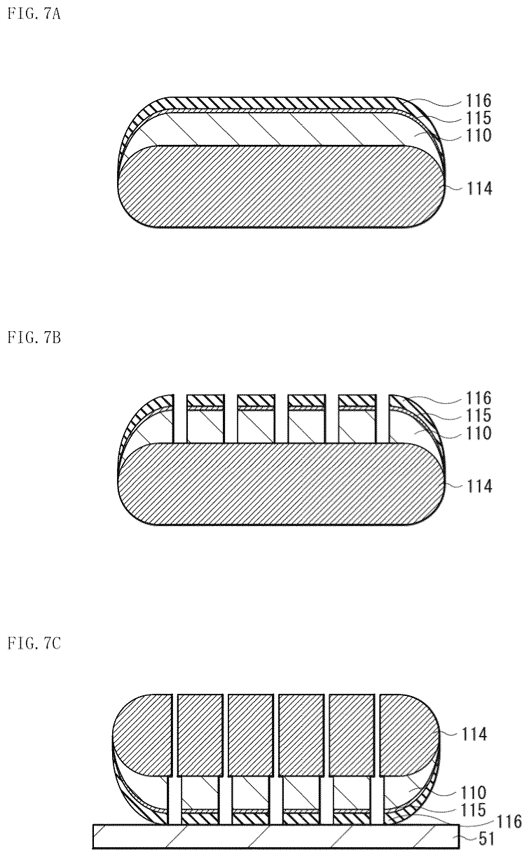

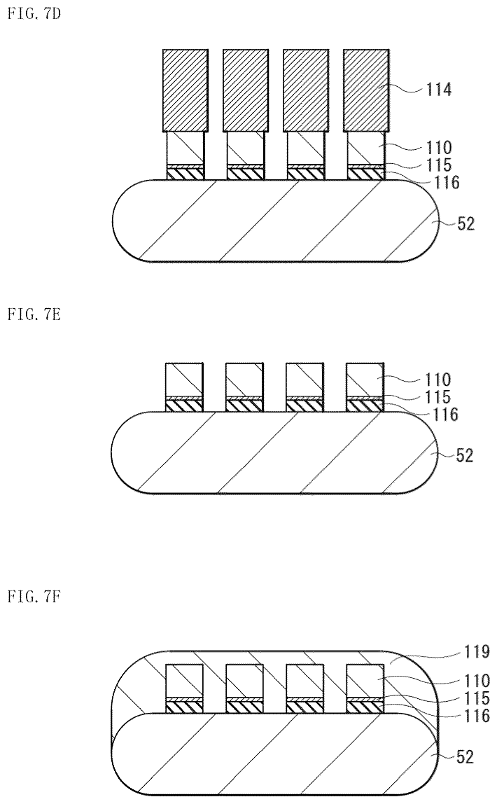

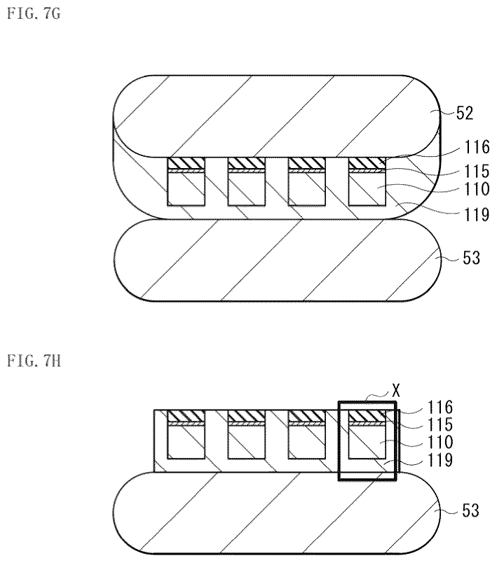

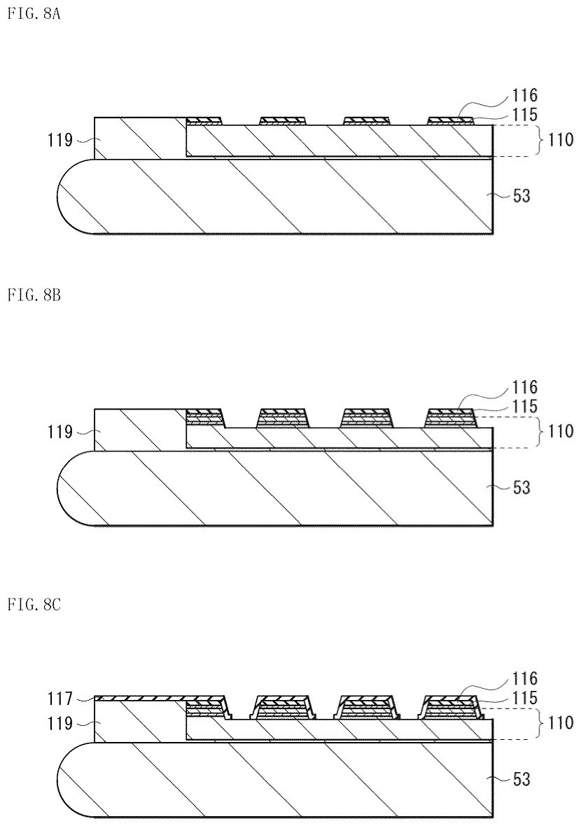

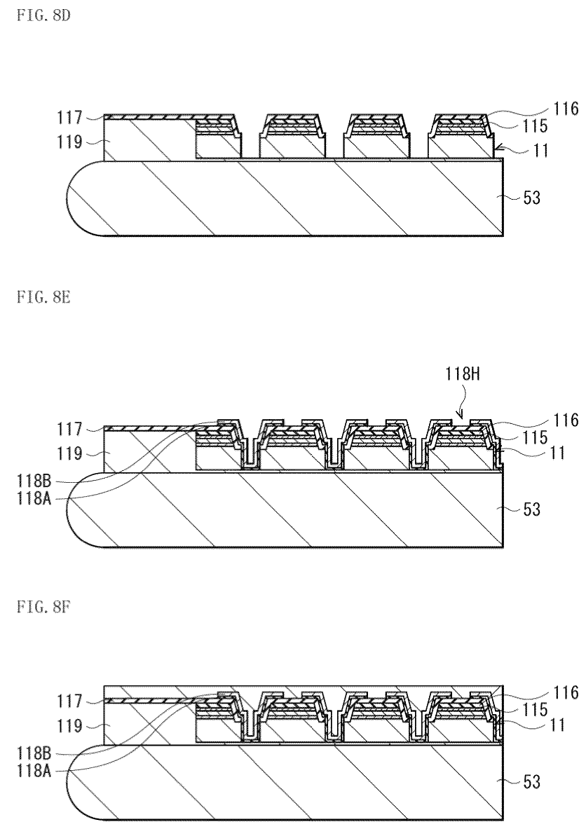

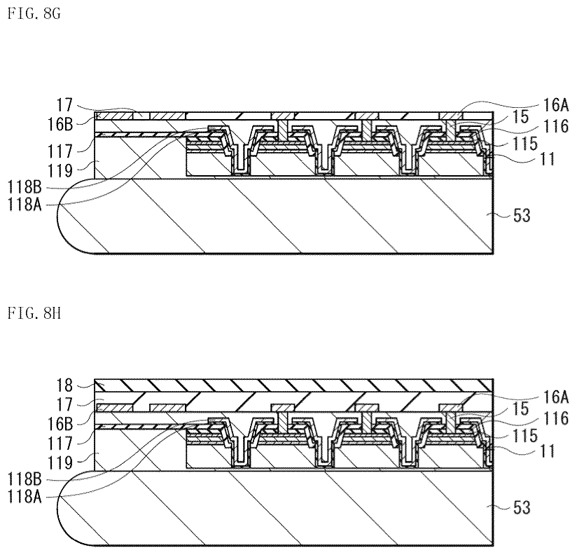

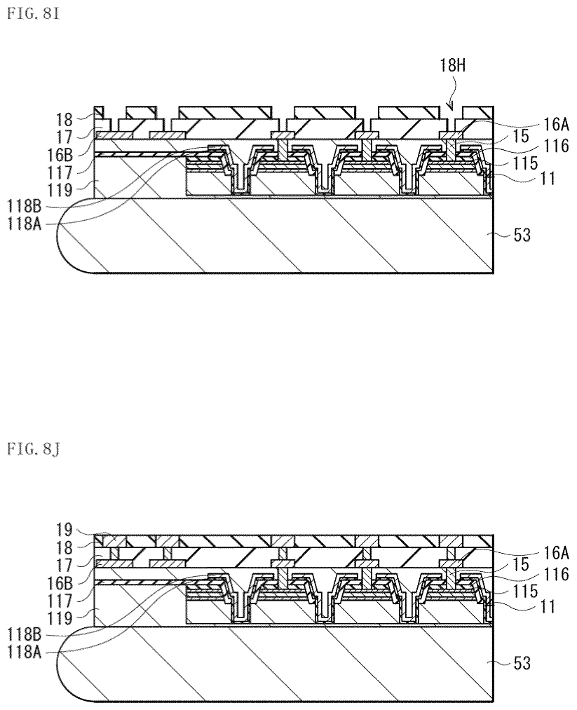

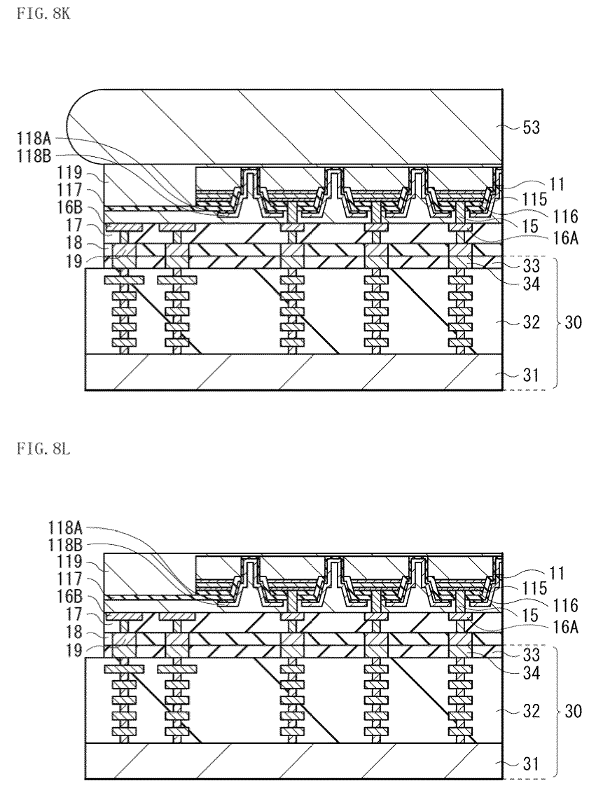

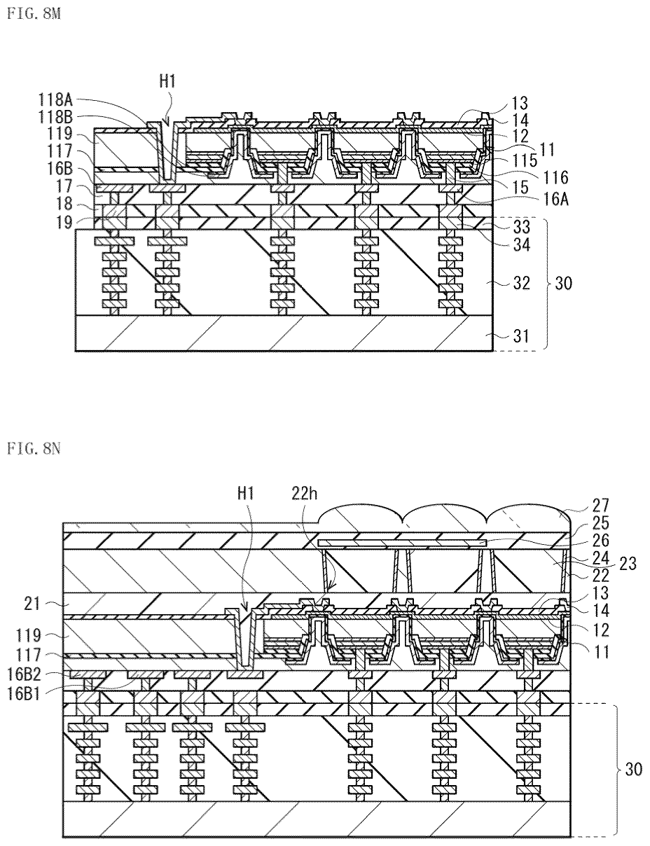

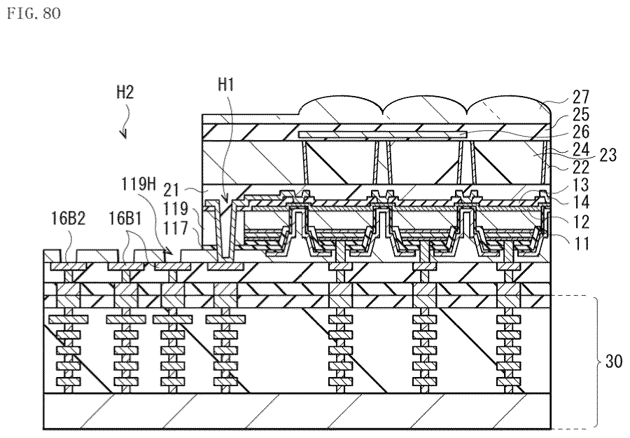

For example, it is possible to manufacture the light emitting device 1 according to the present embodiment as described below. FIG. 7A to FIG. 7H and FIG. 8A to FIG. 8O illustrate an example of manufacturing processes of the light emitting device 1.

First, as illustrated in FIG. 7A, a sapphire substrate 114 is used as a growth substrate, and the compound semiconductor layer 110 is formed through epitaxial crystal growth using molecular-beam epitaxy (MBE), metalorganic chemical vapor deposition (MOCVD), or the like, for example. Next, the electrode layer 115 is formed on the compound semiconductor layer 110 through sputtering, for example, and the insulating layer 116 is formed through chemical vapor deposition (CVD), for example. It is to be noted that though the example of using the sapphire substrate 114 as the growth substrate has been described here, the present disclosure is not limited thereto. Instead of the sapphire substrate 114, a silicon substrate may be used as the growth substrate.

Next, as illustrated in FIG. 7B, patterning is performed through etching the insulating layer 116, the electrode layer 115, and the compound semiconductor layer 110 by using a photolithography technology, for example. Next, as illustrated in FIG. 7C, the sapphire substrate 114 is transferred in such a manner that the insulating layer 116 faces a support substrate 51, and then the sapphire substrate 114 is broken and singulated. Next, as illustrated in FIG. 7D, the singulated sapphire substrates 114 are bonded to a support substrate 52 in such a manner that he insulating layers 116 face the support substrate 52.

Next, as illustrated in FIG. 7E, the sapphire substrates 114 are removed through, for example, grinding/polishing, and surfaces of the compound semiconductor layers 110 are planarized. Next, as illustrated in FIG. 7F, the embedding layer 119 is formed on the support substrate 52 through the CVD for example, and is planarized. Next, as illustrated in FIG. 7G, the embedding layer 119 is joined to a support substrate 53 through plasma bonding for example. Subsequently, as illustrated in FIG. 7H, the support substrate 52 is peeled off. Next, a portion in a frame X in FIG. 7H will be enlarged and described.

First, as illustrated in FIG. 8A, patterning is performed through etching the insulating layer 116 and the electrode layer 115 by using the photolithography technology, for example. Next, as illustrated in FIG. 8B, a portion of the compound semiconductor layer is etched through the photolithography technology for example, to form a mesa structure including the first conductivity-type layer 111, the active layer 112, and a portion of the second conductivity-type layer 113.

Next, an AlO film is formed over the upper surface of the insulating layer 116 and the side surfaces of the insulating layer 116, the electrode layer 115, and the mesa structure including the first conductivity-type layer 111, the active layer 112, and the second conductivity-type layer 113, and a bottom surface through, for example, atomic layer deposition (ALD), and then an SiO₂ film is further formed through the CVD, for example. Subsequently, the SiO₂ film is etched through, for example, the photolithography technology to form the protection layer 117 as a sidewall on the upper surface and the side surface of the mesa structure as illustrated in FIG. 8C.

Next, for example, as illustrated in FIG. 8D, the plurality of light emitting elements 11 is formed by separating the second conductivity-type layer 113 exposed from the protection layer 117 through the photolithography technology, for example. Next, an AlO film is formed through, for example, the ALD to cover the upper surface of the protection layer 117 and the side surface of the exposed light emitting element 11. Next, as illustrated in FIG. 8E, the insulating film 118A and reflection film 118B are sequentially formed through, for example, the CVD, and then the opening 118H is made in the upper surface of the mesa structure.

Next, as illustrated in FIG. 8F, the embedding layer 119 for planarization is formed again through, for example, the CVD. Subsequently, as illustrated in FIG. 8G, the plugs 15 for the respective light emitting elements 11 and the insulating layer 17 embedded with the plurality of pad sections 16A and the pad connection layer 16B are formed. Next, as illustrated in FIG. 8H, the insulating layer 17 is thickened, and the insulating layer 18 is formed on the insulating layer 17.

Next, as illustrated in FIG. 8I, openings 18H are made above the respective pad sections 16A and the respective pad connection layers 16B. Subsequently, as illustrated in FIG. 8J, the plurality of pad electrodes 19 are formed by embedding, for example, Cu into the openings 18H. Subsequently, surfaces of the insulating layer 18 and the plurality of pad electrodes 19 are polished through, for example, CMP to planarize the joint surface to be joined to the driving circuit substrate 30.

Next, as illustrated in FIG. 8K, through hybrid bonding, the plurality of pad electrodes 19 is bonded to the plurality of pad electrodes 34 of the driving circuit substrate 30 that has been formed separately. Subsequently, as illustrated in FIG. 8L, the support substrate 55 is peeled off. Next, as illustrated in FIG. 8M, an ITO film is formed through the sputtering for example, and then the ITO film is patterned through the photolithography technology for example, to form the electrode layer 12. Next, as illustrated in FIG. 8M, the insulating layer 13 is formed through the CVD for example. Subsequently, through the photolithography technology, openings are made between the adjacent light emitting elements 11 and the opening H1 that reaches the pad connection layer 16B is made. Next, as illustrated in FIG. 8M, a stacked film of Ti/W is formed through the CVD for example, and then the extraction electrode 14 is formed by patterning the stacked film through the photolithography technology for example.

Next, as illustrated in FIG. 8N, the planarizing layer 21 and the partition wall layer 22 are sequentially formed through the CVD, for example. Next, as illustrated in FIG. 8N, the openings 22H are made in the partition wall layer 22 above the respective light emitting elements 11 through the photolithography technology for example. Next, as illustrated in FIG. 8N, the reflection films 24 are formed on side surfaces of the openings 22H by forming Al films on an upper surface of the partition wall layer 22 and the side surfaces and bottom surfaces of the openings 22H through the CVD for example, and then removing the Al films formed on the upper surface of the partition wall layer 22 and the bottom surfaces of the openings 22H through etchback. Next, as illustrated in FIG. 8N, the wavelength conversion layers 23 (23R, 23G, and 23B) for respective colors are formed in the openings 22H through a coating method such as an inkjet method for example. Subsequently, the protection layer 25 including the wavelength selective layer 26 is formed on the partition wall layer 22 and the wavelength conversion layers 23, and then the on-chip lens layer 27 is formed.

Next, for example, through the etching, the dug section H2 that reaches the embedding layer 119 under the protection layer 117 is formed outside the display section 100A including the plurality of light emitting elements 11 arranged in the array form as illustrated in FIG. 8O. Next, as illustrated in FIG. 8O, the mounting connection terminal 16B1 and the external connection terminal 16B2 are exposed by making the respective openings 119H above the mounting connection terminal 16B 1 and the external connection terminal 16B2 through the photolithography technology, for example. Subsequently, in the dug section H2, the mounting connection terminal 16B1 is coupled to the DDIC 29 via the bumps 28 for example, and the external connection terminal 16B2 is coupled to the flexible substrate, as appropriate. In such a way, the light emitting device 1 illustrated in FIG. 1 is obtained.

### 1-3. Actions and Effects

With regard to the light emitting device 1 according to the present embodiment, the mounting connection terminal 16B1 and the external connection terminal 16B2 to be coupled to the DDIC 29, the flexible substrate, or the like are closer to the element substrate 10 than the joint surface between the driving circuit substrate 30 and the element substrate 10. This makes it easier to couple the mounting connection terminal 16B1 and the external connection terminal 16B2 to functional elements such as the DDIC 29 or the flexible substrate. A description thereof will be provided below.

For example, in a case of a general image display element including a nitride semiconductor layer constituting an LED and a driving circuit substrate that are coupled through the hybrid bonding, a connection pad to be coupled to an external power source is disposed on the driving-circuit-substrate side. This tends to cause connection failure of the connection pad when mounting the DDIC, the flexible substrate, or the like, and this has become a cause of reduction in production yield.

On the contrary, according to the present embodiment, the mounting connection terminal 16B1 and the external connection terminal 16B2 are closer to the element-substrate 10 side than the joint surface between the driving circuit substrate 30 and the element substrate 10 as described above. This makes it easier to couple the mounting connection terminal 16B1 and the external connection terminal 16B2 to the DDIC 29, the flexible substrate, or the like when mounting the DDIC 29, the flexible substrate, or the like.

As described above, it becomes possible to improve production yield of the light emitting device 1 and the image display device 100 provided with the same according to the present embodiment.

In addition, in the case of the light emitting device 1 according to the present embodiment, the pad connection layer 16B3 coupled to the extraction electrode 14 constituting the common electrode for the plurality of light emitting elements 11 together with the electrode layer 12 is routed in the element substrate 10 without passing through the driving circuit substrate 30 and is coupled to the external power source. This makes it possible to energize the cathode electrode without passing through the driving circuit substrate 30, the cathode electrode being the common electrode for the plurality of light emitting elements 11 and including the electrode layer 12 and the extraction electrode 14 into which large electric current is crowded. Therefore, it becomes possible to improve its reliability.

Next, first to 12th modifications and application examples of the present disclosure will be described. It is to be noted that structural elements corresponding to the above-described structural elements of the light emitting device 1 according to the above-described embodiment will be denoted with the same reference signs as the above-described embodiment, and repeated description will be omitted.

### 2. Modifications

### (2-1. First Modification)

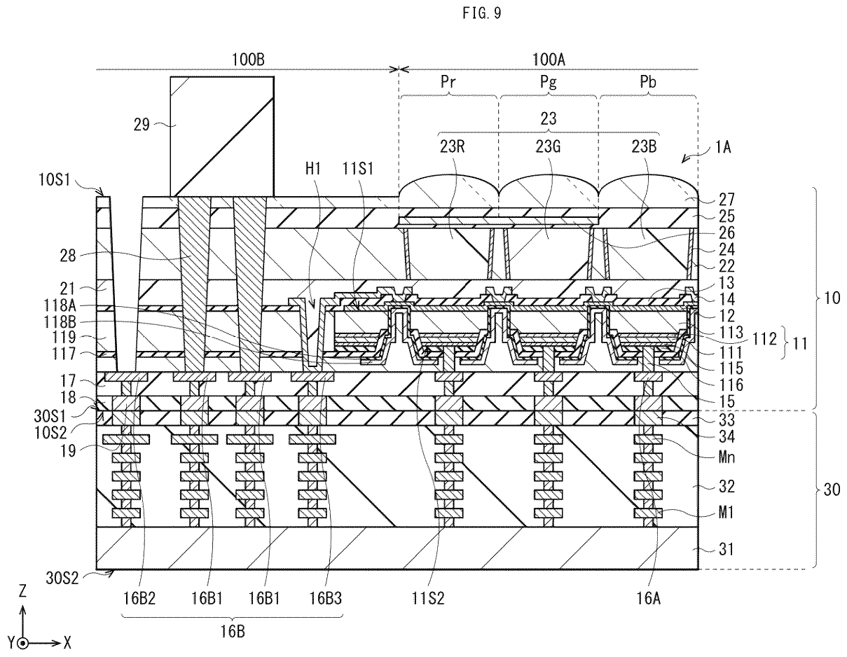

FIG. 9 schematically illustrates an example of a cross-sectional configuration of a light emitting device (light emitting device 1A) according to a first modification of the present disclosure. In a way similar to the above-described embodiment, the light emitting device 1A is suitably applicable to a display section of an image display device (for example, image display device 100) which is a so-called LED display.

In the above-described embodiment, the example in which the dug section H2 is formed in such a manner that the dug section H2 penetrates the on-chip lens layer 27, the protection layer 25, the partition wall layer 22, the planarizing layer 21, the insulating layer 13, and the protection layer 117 and reaches the embedding layer 119 under the protection layer 117 and the DDIC 29 is mounted on the embedding layer 119 has been described. On the contrary, the light emitting device 1A according to the present modification does not include the dug section H2 but the DDIC 29 is mounted on the on-chip lens layer 27.

As described above, the light emitting device 1A according to the present modification does not include the dug section H2 but the DDIC 29 is mounted on the on-chip lens layer 27. Even in this case, it is easier to couple the mounting connection terminal 16B1 and the external connection terminal 16B2 to the DDIC 29, the flexible substrate, or the like than the general image display element in which a connection pad to be coupled to an external power source is disposed on the driving-circuit-substrate side. Therefore, this makes it possible to improve the production yield in a way similar to the light emitting device 1 according to the above-described embodiment,

### (2-2. Second Modification)

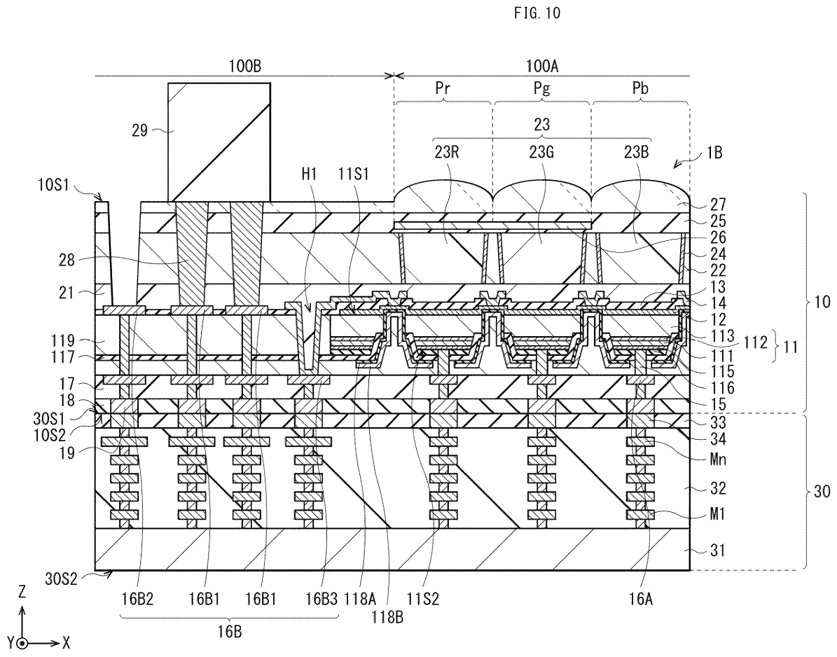

FIG. 10 schematically illustrates an example of a cross-sectional configuration of a light emitting device (light emitting device 1B) according to a second modification of the present disclosure. In a way similar to the above-described embodiment, the light emitting device 1B is suitably applicable to the display section of the image display device (for example, image display device 100) which is a so-called LED display.

In the above-described embodiment, the example in which the mounting connection terminal 16B1 and the external connection terminal 16B2 are provided in the insulating layer 17 and the dug section H2 is formed in such a manner that the dug section H2 penetrates the on-chip lens layer 27, the protection layer 25, the partition wall layer 22, the planarizing layer 21, the insulating layer 13, and the protection layer 117 and reaches the embedding layer 119 under the protection layer 117 has been described. On the contrary, the light emitting device 1B according to the present modification does not include the dug section H2, but the mounting connection terminal 16B1 and the external connection terminal 16B2 are formed on the embedding layer 119 successive to the surface 11S1 of the plurality of light emitting elements 11, and the DDIC 29 is mounted on the on-chip lens layer 27.

As described above, the light emitting device 1A according to the present modification does not include the dug section H2, but the mounting connection terminal 16B1 and the external connection terminal 16B2 are provided closer to the light exit surface (surface 10S1 when mounting the DDIC 29 on the on-chip lens layer 27. This makes it easier to couple the mounting connection terminal 16B1 and the external connection terminal 16B2 to the DDIC 29, the flexible substrate, or the like in comparison with the first modification described above. Therefore, this makes it possible to improve the production yield in a way similar to the light emitting device 1 according to the above-described embodiment.

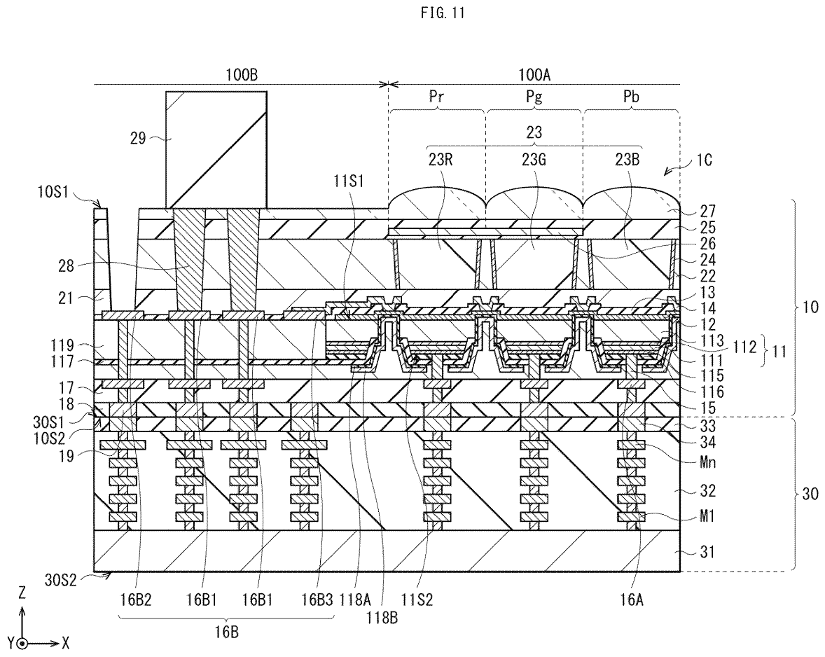

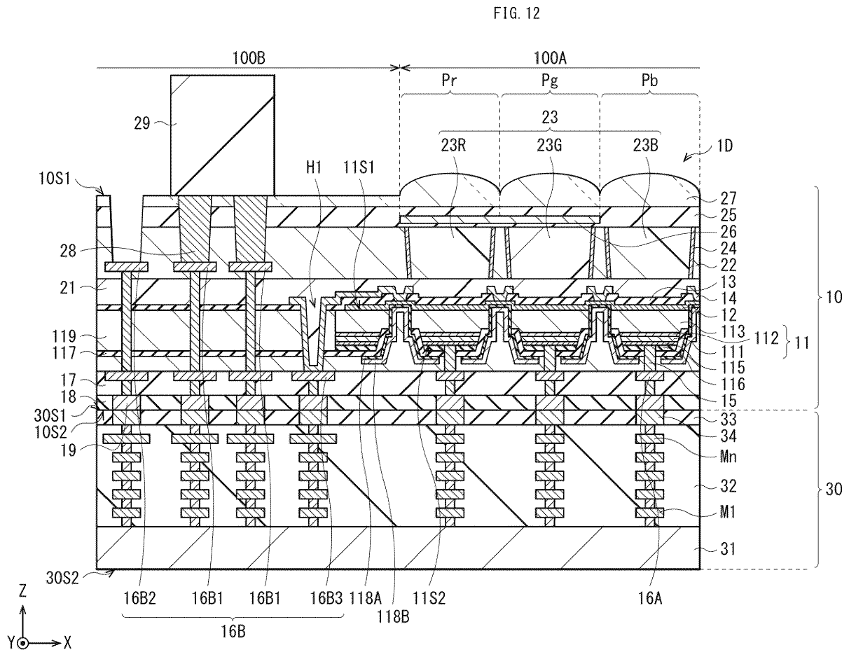

In addition, the example in which the pad connection layer 16B3 coupled to the extraction electrode 14 is provided in the insulating layer 17 has been described in the above-described embodiment. However, the present technology is not limited thereto. In a case of a light emitting device 1C illustrated in FIG. 11, the pad connection layer 16B3 coupled to the extraction electrode 14 may be formed on the embedding layer 119.

### (2-3. Third Modification)

FIG. 12 schematically illustrates an example of a cross-sectional configuration of a light emitting device (light emitting device 1D) according to a third modification of the present disclosure. In a way similar to the above-described embodiment, the light emitting device 1D is suitably applicable to the display section of the image display device (for example, image display device 100) Which Is a So-called Led Display.

According to the above-described second modification, the dug section H2 is not formed, but the mounting connection terminal 16B1 and the external connection terminal 16B2 are formed on the embedding layer 119 successive to the surface 11S1 of the plurality of light emitting elements 11, and the DDIC 29 is mounted on the on-chip lens layer 27. On the contrary, in a case of the light emitting device 1D according to the present modification, the mounting connection terminal 16B1 and the external connection terminal 16B2 are formed in the partition wall layer 22.

### (2-4. Fourth Modification)

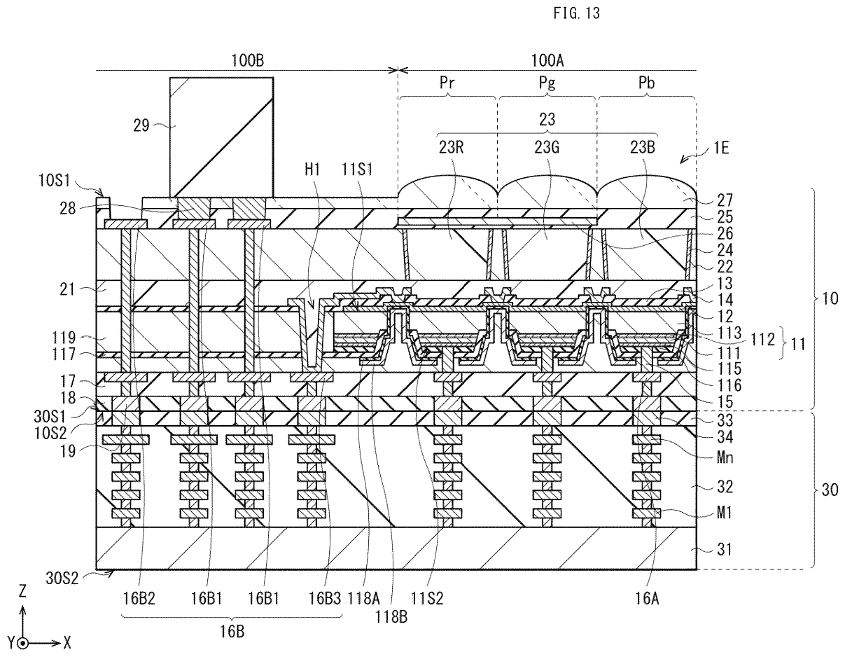

FIG. 13 schematically illustrates an example of a cross-sectional configuration of a light emitting device (light emitting device 1E) according to a fourth modification of the present disclosure. In a way similar to the above-described embodiment, the light emitting device 1E is suitably applicable to the display section of the image display device (for example, image display device 100) which is a so-called LED display.

According to the above-described second modification, the dug section H2 is not formed, but the mounting connection terminal 16B1 and the external connection terminal 16B2 are formed on the embedding layer 119 successive to the surface 11S1 of the plurality of light emitting elements 11, and the DDIC 29 is mounted on the on-chip lens layer 27. On the contrary, in a case of the light emitting device 1E according to the present modification, the mounting connection terminal 16B1 and the external connection terminal 16B2 are formed on the partition wall layer 22.

As described in the second to fourth modifications, positions of the mounting connection terminal 16B1 and the external connection terminal 16B2 are not specifically limited as long as they are closer to the element substrate 10 than the joint surface between the driving circuit substrate 30 and the element substrate 10. Therefore, this makes it possible to improve the production yield in a way similar to the above-described embodiment. Also, positions of the pad connection layer 16B3 to be coupled to the extraction electrode 14 are not specifically limited as long as it is closer to the element substrate 10 than the joint surface between the driving circuit substrate 30 and the element substrate 10. Therefore, this makes it possible to improve its reliability in a way similar to the above-described embodiment.

### (2-5. Fifth Modification)

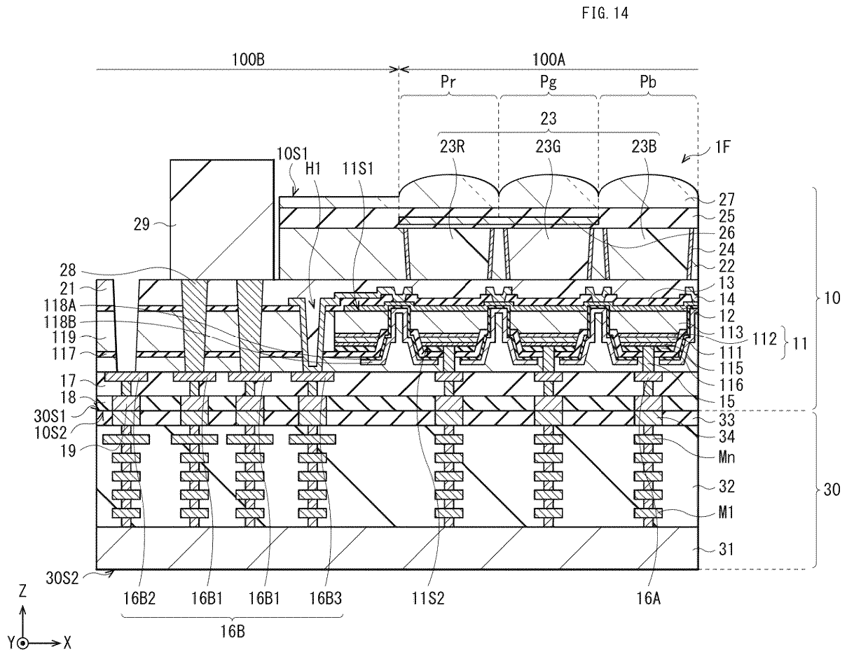

FIG. 14 schematically illustrates an example of a cross-sectional configuration of a light emitting device (light emitting device 1F) according to a fifth modification of the present disclosure. In a way similar to the above-described embodiment, the light emitting device 1F is suitably applicable to the display section of the image display device (for example, image display device 100) which is a so-called LED display.

In the above-described embodiment, the example in which the dug section H2 is formed in such a manner that the dug section H2 penetrates the on-chip lens layer 27, the protection layer 25, the partition wall layer 22, the planarizing layer 21, the insulating layer 13, and the protection layer 117 and reaches the embedding layer 119 under the protection layer 117 and the DDIC 29 is mounted on the embedding layer 119 has been described. On the contrary, the light emitting device 1F according to the present modification includes a dug section H2 that penetrates the on-chip lens layer 27, the protection layer 25, and the partition wall layer 22 and that reaches the planarizing layer 21, and the DDIC 29 is mounted on the planarizing layer 21.

As described above, the light emitting device 1F according to the present modification includes the dug section H2 that penetrates the on-chip lens layer 27, the protection layer 25, and the partition wall layer 22 and that reaches the planarizing layer 21, and the DDIC 29 is mounted on the planarizing layer 21. Even in such a case, this makes it possible to improve the production yield in a way similar to the light emitting device 1 according to the above-described embodiment.

### (2-6. Sixth Modification)

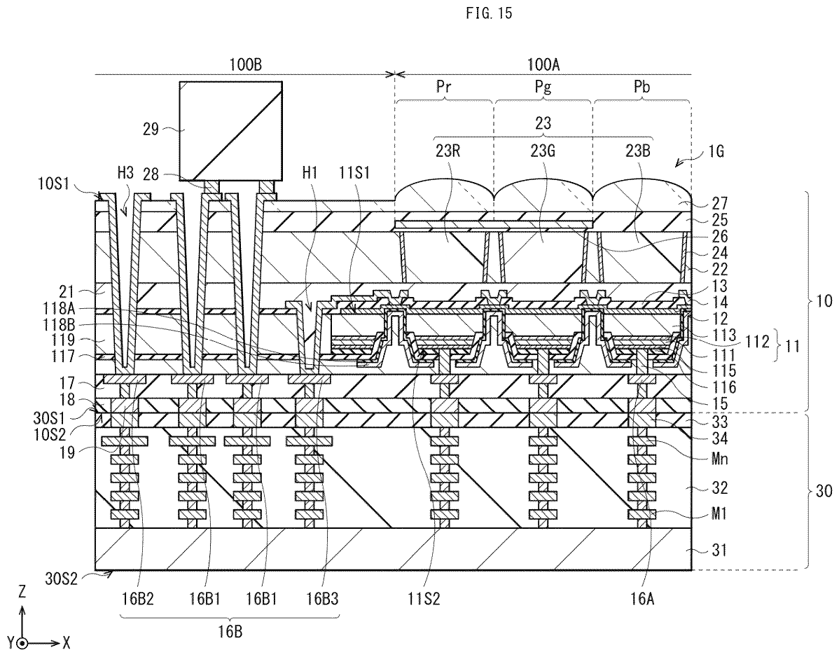

FIG. 15 schematically illustrates an example of a cross-sectional configuration of a light emitting device (light emitting device 1G) according to a sixth modification of the present disclosure. In a way similar to the above-described embodiment, the light emitting device 1G is suitably applicable to the display section of the image display device (for example, image display device 100) which is a so-called LED display.

According to the above-described first modification, the DDIC 29 mounted on the on-chip lens layer 27 is coupled to the mounting connection terminal 16B1 via the bump 28. On the contrary, in a case of the light emitting device 1G according to the present modification, a sputtered film 281 is formed in an opening H3 that reaches the mounting connection terminal 16B1 and the external connection terminal 16B2 formed in the insulating layer 17, and the DDIC 29 is mounted via the sputtered film 281 and the bump 28 formed on the sputtered film 281.

As described above, forms of coupling of the mounting connection terminal 16B1/external connection terminal 16B2 and the DDIC 29, the flexible substrate, or the like are not specifically limited. ps (2-7. Seventh Modification)

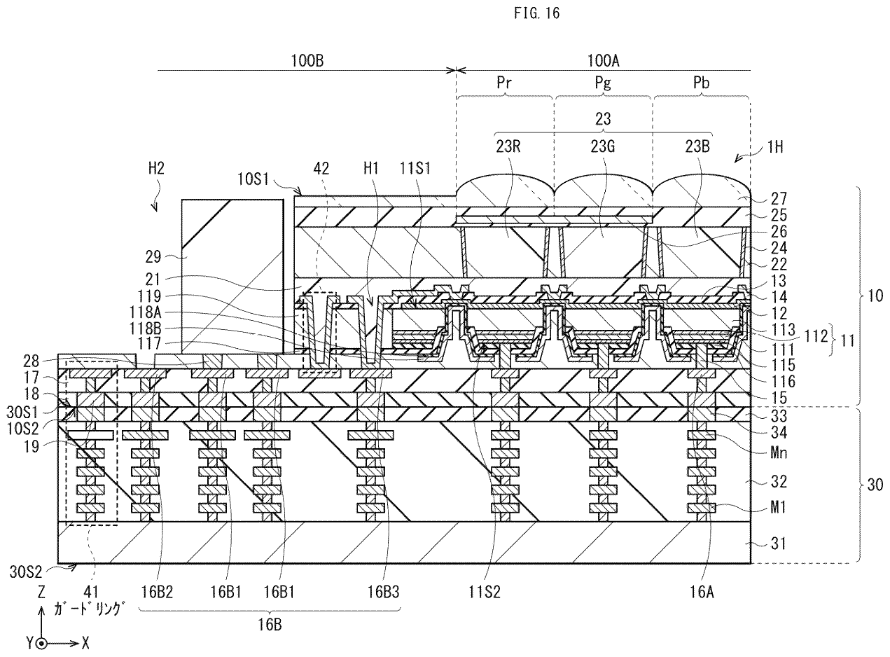

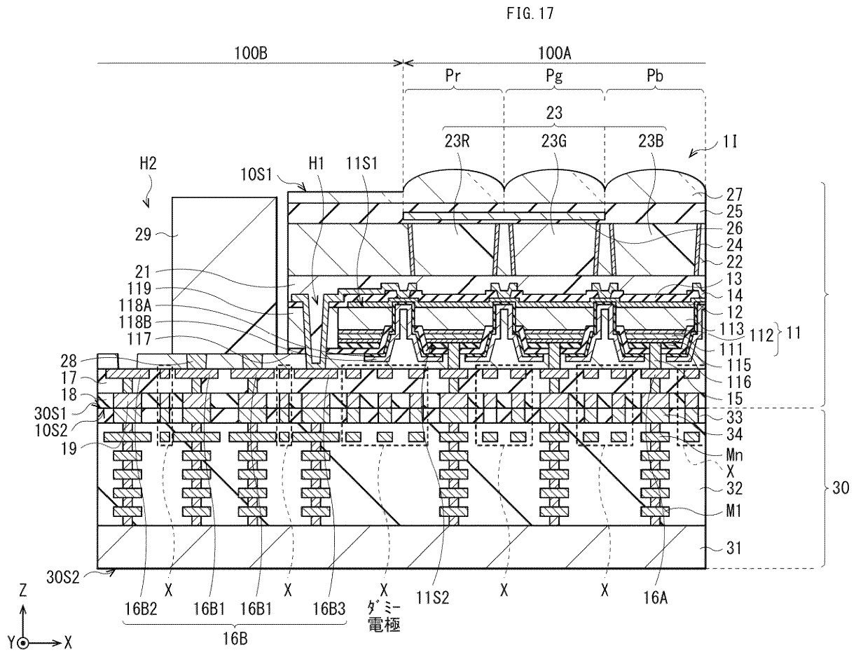

FIG. 16 schematically illustrates an example of a cross-sectional configuration of a light emitting device (light emitting device 1H) according to a seventh modification of the present disclosure. In a way similar to the above-described embodiment, the light emitting device 1H is suitably applicable to the display section of the image display device (for example, image display device 100) which is a so-called LED display.

As illustrated in FIG. 16, respective ends of the element substrate 10 and the driving circuit substrate 30 may be provided with guard rings 41 and 42. This makes it possible to prevent generation of cracks due to dicing of the element substrate 10 and the driving circuit substrate 30 and ingress of water or the like associated therewith. Therefore, this makes it possible to improve its reliability in addition to the effects according to the embodiment described above.

### (2-8. Eighth Modification)

FIG. 17 schematically illustrates an example of a cross-sectional configuration of a light emitting device (light emitting device 1I) according to an eighth modification of the present disclosure. In a way similar to the above-described embodiment, the light emitting device 1I is suitably applicable to the display section of the image display device (for example, image display device 100) which is a so-called LED display.

As illustrated in FIG. 17, a plurality of dummy electrodes X may be provided between the plurality of pad electrodes 19, between the plurality of pad electrodes 34, between the plurality of pad sections 16A, between the plurality of pad connection layer 16B, and between the plurality of wirings Mn. The plurality of pad electrodes 19 is embedded in the insulating layer 18, the plurality of pad electrodes 34 is embedded in the insulating layer 33, and the insulating layers 18 and 33 form the joint surface between the driving circuit substrate 30 and the element substrate 10. The plurality of pad sections 16A and the plurality of pad connection layer 16B are formed in the insulating layer 17. The plurality of wirings Mn is formed near the joint surface to be joined to the element substrate 10 in the interlayer insulating layer 32. The plurality of dummy electrodes X is in an electrically floating state and is uninvolved in electric connection and the like between the driving circuit substrate 30 and the element substrate 10. This makes it possible to improve surface flatness of the element substrate 10 and the driving circuit substrate 30, and improve bonding yield.

### (2-9. Ninth Modification)

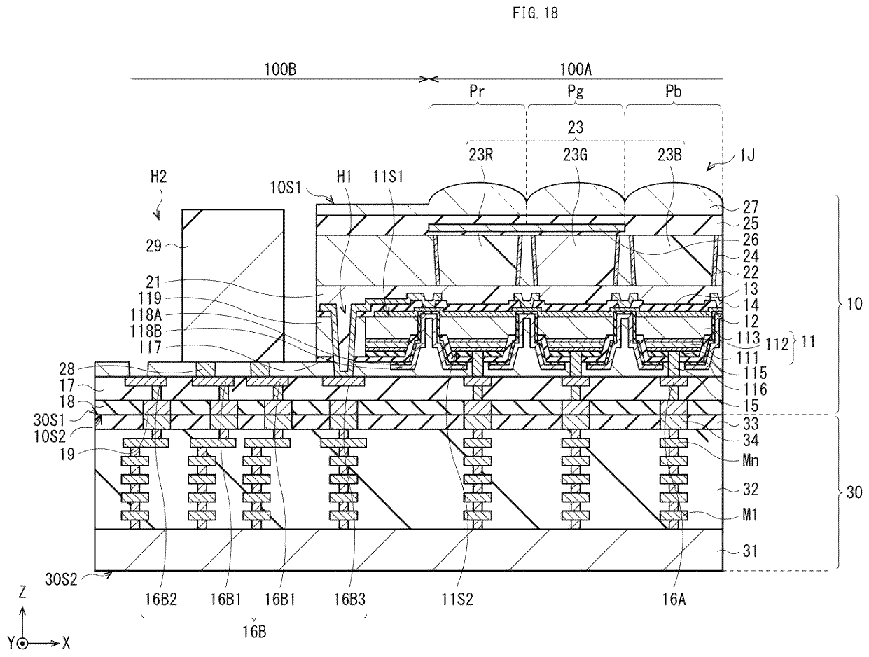

FIG. 18 schematically illustrates an example of a cross-sectional configuration of a light emitting device (light emitting device 1J) according to a ninth modification of the present disclosure. In a way similar to the above-described embodiment, the light emitting device 1J is suitably applicable to the display section of the image display device (for example, image display device 100) which is a so-called LED display.

As illustrated in FIG. 18, the mounting connection terminal 16B1 and the external connection terminal 16B2 may be formed at positions shifted into, for example, an X-axis direction from positions of the plurality of pad electrodes 19 and 34. In other words, the mounting connection terminal 16B1 and the external connection terminal 16B2 may be formed at positions that do not overlap the positions of the plurality of pad electrodes 19 and 34 in plan view. This makes it possible to improve the yield.

### (2-10. Tenth Modification)

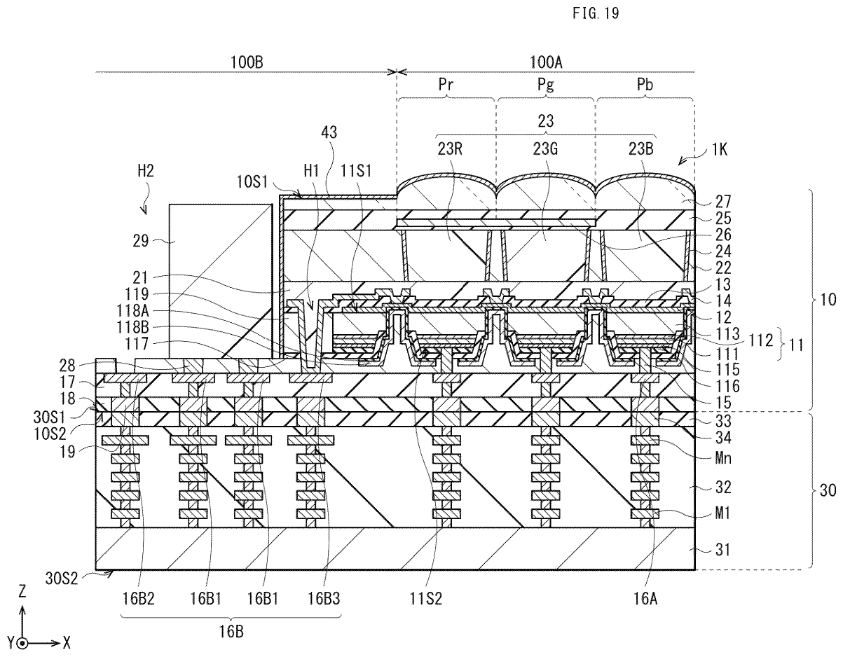

FIG. 19 schematically illustrates an example of a cross-sectional configuration of a light emitting device (light emitting device 1K) according to a ninth modification of the present disclosure. In a way similar to the above-described embodiment, the light emitting device 1K is suitably applicable to the display section of the image display device (for example, image display device 100) which is a so-called LED display.

As illustrated in FIG. 19, a passivation film is preferably formed on side surfaces of the on-chip lens layer 27, the protection layer 25, the partition wall layer 22, the planarizing layer 21, the insulating layer 13, and the protection layer 117. These side surfaces are formed by the dug section H2. It is possible to form the passivation film 43 by using inorganic material such as silicon oxide (SiO), silicon nitride (SiN), or the like formed through the ALD or the like, for example.

This makes it possible to prevent ingress of water or the like into the element substrate 10. Therefore, this makes it possible to improve its reliability in addition to the effects according to the embodiment described above.

### (2-11. 11th Modification)

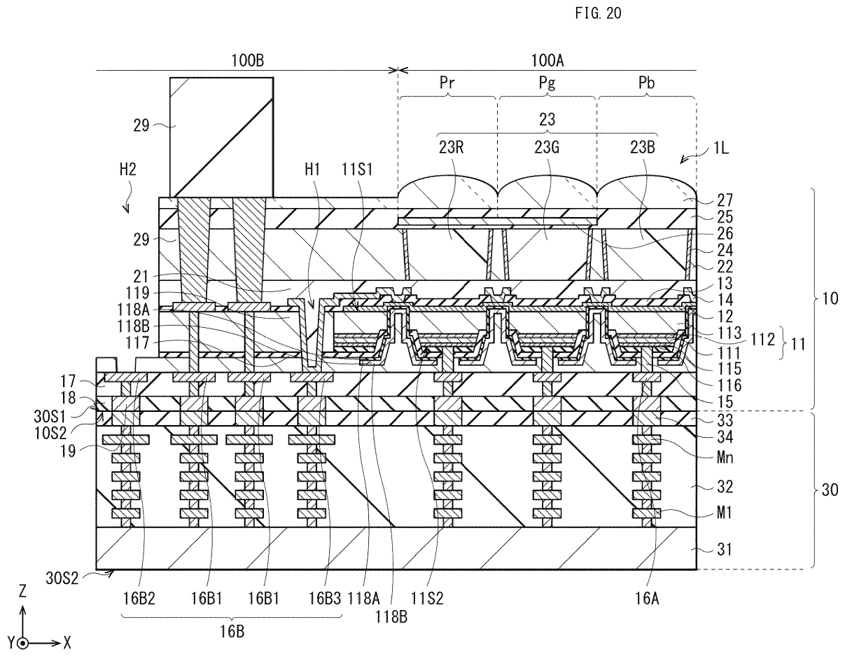

FIG. 20 schematically illustrates an example of a cross-sectional configuration of a light emitting device (light emitting device 1L) according to an 11th modification of the present disclosure. In a way similar to the above-described embodiment, the light emitting device 1L is suitably applicable to the display section of the image display device (for example, image display device 100) which is a so-called LED display.

According to the above-described embodiment or the like, the mounting connection terminal 16B1 and the external connection terminal 16B2 are formed in a same layer. However, the present technology is not limited thereto. As illustrated in FIG. 20, the mounting connection terminal 16B1 and the external connection terminal 16B2 may be formed in different layers. For example, the mounting connection terminal 16B1 may be formed on the embedding layer 119, and the external connection terminal 16B2 may be formed in the insulating layer 17. Even in such a configuration, it is possible to achieve effects that are similar to the above-described embodiment.

### (2-12. 12th Modification)

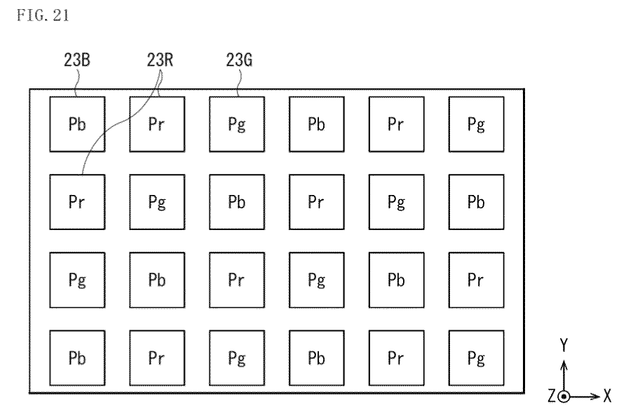

According to the above-described embodiment, the partition wall layer 22 has the substantially regular hexagonal openings 22H for the respective pixels Pr, Pg, and Pb. However, the planar shape of the openings 22H is not limited thereto. For example, as illustrated in FIG. 21, the openings 22H may have a rectangular shape. In this case, the plurality of light emitting elements 11 and the openings 22H may be two-dimensionally arranged in a matrix form, for example. The wavelength conversion layers 23 (red wavelength conversion layer 23A, green wavelength conversion layer 23G, and blue wavelength conversion layer 23B) provided in the respective openings 22H are arrayed according to Bayer arrangement.

### 3. Application Examples

### First Application Example

FIG. 22 is a perspective view illustrating an example of a schematic configuration of an image display device (image display device 100). The image display device 100 is a so-called LED display, and a light emitting device (for example, light emitting device 1) according to the present disclosure is used as display pixels. As illustrated in FIG. 22, for example, the image display device 100 includes a display panel 120 and a control circuit 140 that drives the display panel 120.

The display panel 120 is a display panel in which a mounting substrate 120A and a counter substrate 120B overlap each other. The counter substrate 120B has a surface serving as a picture display surface, and the surface has a display region (display section 100A) in its central part and the frame section 100B serving as a non-display region around the display region

FIG. 23 is a diagram illustrating an example of wiring layout of a region corresponding to the display section 100A on a counter-substrate-120B-side surface of the mounting substrate 120A. As illustrated in FIG. 23, for example, a plurality of data wirings 121 is formed to extend in a predetermined direction and is arranged in parallel at a predetermined pitch in the region corresponding to the display section 100A on the surface of the mounting substrate 120A. The region corresponding to the display section 100A on the surface of the mounting substrate 120A further includes a plurality of scan wirings 122 that extend in a direction intersecting (for example, orthogonal to) the data wirings 121, and the plurality of scan wirings 122 is arranged in parallel at a predetermined pitch, for example. The data wirings 121 and the scan wirings 122 include, for example, conductive material such as Cu.

For example, the scan wiring 122 is formed on an uppermost layer, and is formed on an insulating layer (not illustrated) formed on a surface of a base material, for example. It is to be noted that the base material of the mounting substrate 120A includes, for example, a silicon substrate, a resin substrate, or the like. The insulating layer on the base material includes, for example, SiN, SiO, aluminum oxide (AlO), or resin material. On the other hand, the data wiring 121 is formed in a layer (for example, layer below the uppermost layer) different from the uppermost layer including the scan wiring 122. The data wiring 121 is formed in, for example, the insulating layer on the base material.

Intersections of the data wiring 121 and the scan wiring 122 and their surroundings serve as a display pixel 123. A plurality of the display pixels 123 is arranged in a matrix in the display section 100A. For example, the color pixels Pr, Pg, and Pb of the light emitting device 1 are implemented as the respective display pixels 123.

For example, the light emitting device 1 is provided with a pair of terminal electrodes for the respective color pixel Pr, Pg, and Pb, or is provided with a common terminal electrode and terminal electrodes for the respective color pixel Pr, Pg, and Pb. One of the terminal electrodes is electrically coupled to the data wiring 121, and another terminal electrode is electrically coupled to the scan wiring 122. For example, the one of the terminal electrodes is electrically coupled to a pad electrode 121B at an end of a branch 121A of the data wiring 121. In addition, for example, the other of the terminal electrodes is electrically coupled to a pad electrode 122B at an end of a branch 122A of the scan wiring 122.

For example, the pad electrodes 121B and 122B are formed on the uppermost layer and is provided at parts where the respective light emitting devices 1 are mounted as illustrated in FIG. 23. Here, the pad electrodes 121B and 122B include electrically conductive material such as Au (gold), for example.

The mounting substrate 120A is further provided with, for example, a plurality of support columns (not illustrated) for regulating an interval between the mounting substrate 120A and the counter substrate 120B. The support column may be provided in a region opposed to the display section 100A or may be provided in a region opposed to the frame section 100B.

The counter substrate 120B includes, for example, a glass substrate, a resin substrate, or the like. The counter substrate 120B may have a flat surface on the light-emitting-device 1 side, but preferably has a rough surface. The rough surface may be provided over the whole region opposed to the display section 100A, or may be provided in a region opposed to the display pixels 123 only. The rough surface has fine irregularities into which light emitted from the color pixels Pr, Pg, and Pb enters. It is possible to make the irregularities on the rough surface through sand blasting, dry etching, or the like, for example.

The control circuit 140 drives the respective display pixels 123 (respective light emitting devices 1) on the basis of picture signals. The control circuit 140 includes, for example, a data driver that drives the data wirings 121 coupled to the display pixels 123 and a scan driver that drives the scan wirings 122 coupled to the display pixels 123. For example, as illustrated in FIG. 22, the control circuit 140 may be provided separately from the display panel 120 and may be coupled to the mounting substrate 120A via the wirings, or may be mounted on the mounting substrate 120A.

### (Second Application Example)

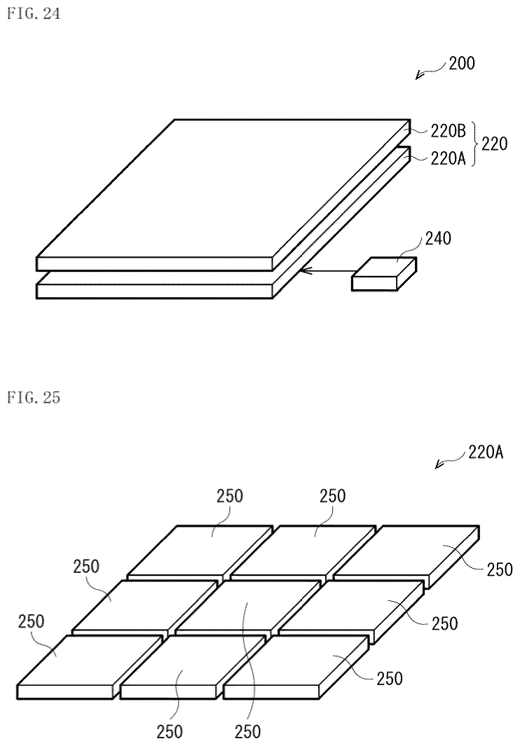

FIG. 24 is a perspective view illustrating another configuration example of the image display device (image display device 200) that uses the light emitting device (for example, light emitting device 1) according to the present disclosure. The image display device 200 is a so-called tiling display that uses a plurality of the light emitting devices including LEDs as light sources. For example, as illustrated in FIG. 24, the image display device 200 includes a display panel 220 and a control circuit 240 that drives the display panel 220.

The display panel 220 is a display panel in which a mounting substrate 220A and a counter substrate 220B overlap each other. The counter substrate 220B has a surface serving as a picture display surface, and the surface has a display section in its central part and a frame section serving as a non-display region around the display section (both sections are not illustrated). For example, the counter substrate 220B is disposed at a position opposed to the mounting substrate 220A with a predetermined gap therebetween. It is to be noted that the counter substrate 220B may be in contact with an upper surface of the mounting substrate 220A.

FIG. 25 schematically illustrates an example of a configuration of the mounting substrate 220A. For example, as illustrated in FIG. 25, the mounting substrate 220A includes a plurality of unit substrates 250 laid like tiles. Although FIG. 25 illustrates the example in which the mounting substrate 220A includes the nine unit substrates 250, the number of unit substrates 250 may be 10 or more or 8 or Less.

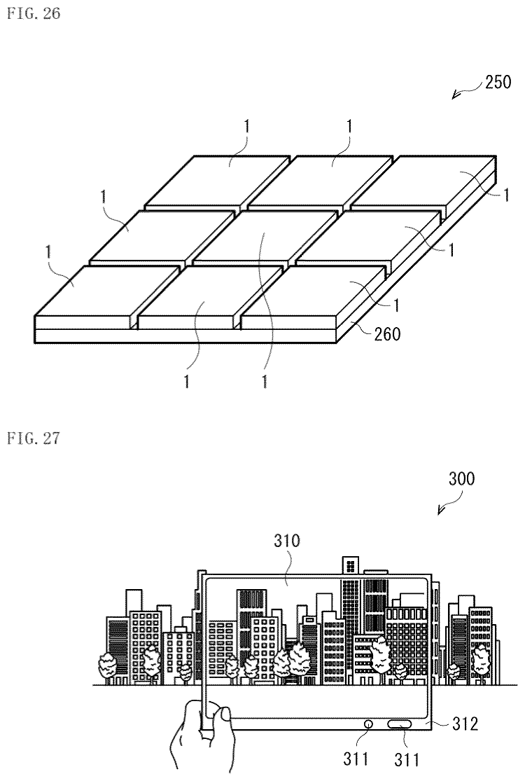

FIG. 26 illustrates an example of a configuration of the unit substrate 250. For example, the unit substrate 250 includes a plurality of light emitting devices 1 laid like tiles and a support substrate 260 that supports the light emitting devices 1. The unit substrate 250 further includes a control substrate (not illustrated). The support substrate 260 is implemented by a metal frame (metal plate), a wiring substrate, or the like, for example. In a case where the support substrate 260 is implemented by the wiring substrate, the support substrate 260 may also serve as the control substrate. In this case, at least one of the support substrate 260 or the control substrate is electrically coupled to the respective light emitting devices 1.

### (Third Application Example)

FIG. 27 illustrates an appearance of a transparent display 300. The transparent display 300 includes, for example, a display section 310, an operation section 311, and a housing 312. The display section 310 uses the light emitting device (for example, light emitting device 1) according to the present disclosure. The transparent display 300 makes it possible to display images, text information, and the like while letting a background of the display section 310 to pass through.

The transparent display 300 includes a mounting substrate that has light transparency. The light emitting device 1 is provided with electrodes, each of which is formed by using electrically conductive material having light transparency like the mounting substrate. Alternatively, the electrodes have a structure that is difficult to be visually recognized by supplementing their wiring width or by thinning the thickness of the wiring. Further, it is possible to display black on the transparent display 300 by superimposing liquid crystal layers provided with a driving circuit, for example. This makes it possible to switch between a transparent mode and a black display mode by controlling a light distribution direction of liquid crystals.

The present technology has been described above with reference to the embodiments, first to 12th modifications, and application examples. However, the present technology is not limited thereto, and various kinds of modifications thereof can be made. For example, the example in which light output from the light emitting element 11 is blue light or ultraviolet light has been described in the above-described embodiment or the like. However, the present technology is not limited thereto. For example, the light emitting device 1 may use light emitting elements that output two or more types of light such as a set of blue light and green light or a set of ultraviolet light and green light.

Further, in the above-described embodiments and the like, the respective members included in the light emitting device 1 and the like have been specifically described, but it is not necessary to include all the members, and other members may be further provided.

It is to be noted that the effects described herein are only for illustrative purposes and there may be other effects.

The present technology may be configured as follows. According to the present technology having the following configurations, the mounting connection terminal and the external connection terminal are formed closer to the element-substrate side than the joint surface between the driving circuit substrate and the element substrate. This makes it easier to couple to an external power source, functional element mounted on the light emitting device, and the like, and this makes it possible to improve the production yield.
(1) A light emitting device including:
   a driving circuit substrate;
   an element substrate that has a first surface opposed to the driving circuit substrate and a second surface serving as a light exit surface on a side opposite to the first surface, that includes a pixel array section including a plurality of light emitting elements arranged in an array form, and that is joined to the driving circuit substrate through hybrid bonding; and
   a mounting connection terminal and an external connection terminal that are electrically coupled to the driving circuit substrate outside the pixel array section and that are closer to the element substrate than a joint surface between the driving circuit substrate and the element substrate.
(2) The light emitting device according to (1), in which
   the mounting connection terminal includes a first pad connection layer,
   the external connection terminal includes a second pad connection layer, and
   the first pad connection layer and the second pad connection layer are formed in a same layer.
(3) The light emitting device according to (2), in which the plurality of light emitting elements includes respective anode electrodes provided on a side of the first surface and a cathode electrode that is common to the plurality of light emitting elements and that is provided on a side of the second surface, and
   the cathode electrode is coupled to an external power source from a side of the element substrate without passing through the driving circuit substrate.
(4) The light emitting device according to any one of (1) to (3), in which the element substrate includes a compound semiconductor layer, an embedding layer, and a first wiring layer, the compound semiconductor layer forming the plurality of light emitting elements and extending to the pixel array section, the embedding layer embedding the plurality of light emitting elements from a side of the driving circuit substrate, the first wiring layer being provided on the side of the driving circuit substrate of the embedding layer and forming a joint surface to be joined to the driving circuit substrate.
(5) The light emitting device according to any one of (1) to (4), in which the mounting connection terminal is coupled to a display drive IC.
(6)

The light emitting device according to any one of (1) to (4), in which the external connection terminal is coupled to a flexible substrate or a printed wiring board.
(7) The light emitting device according to (4), in which
   the element substrate further includes a dug section that is obtained by digging the embedding layer from a side of the second surface,
   the mounting connection terminal is provided in the first wiring layer, and the display drive IC coupled to the mounting connection terminal is disposed in the dug section.
(8) The light emitting device according to (4), in which
   the embedding layer and the compound semiconductor layer form the second surface,
   the mounting connection terminal is provided in the first wiring layer, and
   the display drive IC coupled to the mounting connection terminal is disposed on the second surface.
(9) The light emitting device according to (4), in which
   the element substrate further includes a wavelength conversion layer, a protection layer, and a micro lens layer that are stacked in this order on a side of the second surface of the embedding layer and the compound semiconductor layer, the wavelength conversion layer converting a wavelength of light emitted from the plurality of light emitting elements of the pixel array section, the micro lens layer outputting the light emitted from the plurality of light emitting elements of the pixel array section into a predetermined direction, and
   the display drive IC coupled to the mounting connection terminal is disposed on the second surface.
(10) The light emitting device according to (9), in which the display drive IC coupled to the mounting connection terminal is disposed on the micro lens layer.
(11) The light emitting device according to (9) or (10), in which the mounting connection terminal is provided in the first wiring layer.
(12) The light emitting device according to (9) or (10), in which the mounting connection terminal is provided on the embedding layer.
(13) The light emitting device according to (9) or (10), in which the mounting connection terminal is provided in the wavelength conversion layer.
(14) The light emitting device according to (9) or (10), in which the mounting connection terminal is provided on the wavelength conversion layer.
(15) The light emitting device according to any one of (1) to (14), in which the driving circuit substrate further includes a first guard ring provided near an end of the driving circuit substrate.
(16) The light emitting device according to any one of (4) to (15), in which the element substrate further includes a second guard ring provided in the embedding layer near the dug section.
(17) The light emitting device according to any one of (1) to (16), in which the element substrate and the driving circuit substrate further include, on the joint surface therebetween, a plurality of first pad electrodes and a plurality of second pad electrodes, the plurality of first pad electrodes electrically coupling the element substrate and the driving circuit substrate to each other, the plurality of second pad electrodes electrically floating.
(18) The light emitting device according to any one of (2) to (17), in which
   the element substrate and the driving circuit substrate further include, on the joint surface therebetween, a plurality of first pad electrodes electrically coupling the element substrate and the driving circuit substrate to each other, and
   the first pad connection layer, the second pad connection layer, and the plurality of first pad electrodes are formed at positions that the first pad connection layer and the second pad connection layer do not overlap the plurality of first pad electrodes in plan view.
(19) The light emitting device according to any one of (9) to (18), in which the element substrate further includes a protection film including inorganic material, the protection film covering side surfaces of the micro lens layer, the protection layer, the wavelength conversion layer, and the embedding layer.
(20) An image display device including
   a light emitting device including
      a driving circuit substrate,
      an element substrate that has a first surface opposed to the driving circuit substrate and a second surface serving as a light exit surface on a side opposite to the first surface, that includes a pixel array section including a plurality of light emitting elements arranged in an array form, and that is joined to the driving circuit substrate through hybrid bonding, and
      a mounting connection terminal and an external connection terminal that are electrically coupled to the driving circuit substrate outside the pixel array section and that are closer to the element substrate than a joint surface between the driving circuit substrate and the element substrate.

The present application claims the benefit of Japanese Priority Patent Application JP2023-024684 filed with the Japan Patent Office on Feb. 20, 2023, the entire contents of which are incorporated herein by reference.

It should be understood by those skilled in the art that various modifications, combinations, sub-combinations and alternations may occur depending on design requirements and other factors insofar as they are within the scope of the appended claims or the equivalents thereof.

What is claimed is:

1. A light emitting device, comprising:
a driving circuit substrate;
an element substrate that has a first surface opposed to the driving circuit substrate and a second surface serving as a light exit surface on a side opposite to the first surface, that includes a pixel array section including a plurality of light emitting elements arranged in an array form, and that is joined to the driving circuit substrate through hybrid bonding; and
a mounting connection terminal and an external connection terminal that are electrically coupled to the driving circuit substrate outside the pixel array section and that are closer to the element substrate than a joint surface between the driving circuit substrate and the element substrate.

2. The light emitting device according to claim 1, wherein
the mounting connection terminal includes a first pad connection layer,
the external connection terminal includes a second pad connection layer, and
the first pad connection layer and the second pad connection layer are formed in a same layer.

3. The light emitting device according to claim 2, wherein
the plurality of light emitting elements includes respective anode electrodes provided on a side of the first surface and a cathode electrode that is common to the plurality of light emitting elements and that is provided on a side of the second surface, and
the cathode electrode is coupled to an external power source from a side of the element substrate without passing through the driving circuit substrate.

4. The light emitting device according to claim 1, wherein the element substrate includes a compound semiconductor layer, an embedding layer, and a first wiring layer, the compound semiconductor layer forming the plurality of light emitting elements and extending to the pixel array section, the embedding layer embedding the plurality of light emitting elements from a side of the driving circuit substrate, the first wiring layer being provided on the side of the driving circuit substrate of the embedding layer and forming a joint surface to be joined to the driving circuit substrate.

5. The light emitting device according to claim 1, wherein the mounting connection terminal is coupled to a display drive IC.

6. The light emitting device according to claim 1, wherein the external connection terminal is coupled to a flexible substrate or a printed wiring board.

7. The light emitting device according to claim 4, wherein
the element substrate further includes a dug section that is obtained by digging the embedding layer from a side of the second surface,
the mounting connection terminal is provided in the first wiring layer, and
the display drive IC coupled to the mounting connection terminal is disposed in the dug section.

8. The light emitting device according to claim 4, wherein
the embedding layer and the compound semiconductor layer form the second surface,
the mounting connection terminal is provided in the first wiring layer, and
the display drive IC coupled to the mounting connection terminal is disposed on the second surface.

9. The light emitting device according to claim 4, wherein
the element substrate further includes a wavelength conversion layer, a protection layer, and a micro lens layer that are stacked in this order on a side of the second surface of the embedding layer and the compound semiconductor layer, the wavelength conversion layer converting a wavelength of light emitted from the plurality of light emitting elements of the pixel array section, the micro lens layer outputting the light emitted from the plurality of light emitting elements of the pixel array section into a predetermined direction, and
the display drive IC coupled to the mounting connection terminal is disposed on the second surface.

10. The light emitting device according to claim 9, wherein the display drive IC coupled to the mounting connection terminal is disposed on the micro lens layer.

11. The light emitting device according to claim 9, wherein the mounting connection terminal is provided in the first wiring layer.

12. The light emitting device according to claim 9, wherein the mounting connection terminal is provided on the embedding layer.

13. The light emitting device according to claim 9, wherein the mounting connection terminal is provided in the wavelength conversion layer.

14. The light emitting device according to claim 9, wherein the mounting connection terminal is provided on the wavelength conversion layer.

15. The light emitting device according to claim 1, wherein the driving circuit substrate further includes a first guard ring provided near an end of the driving circuit substrate.

16. The light emitting device according to claim 4, wherein the element substrate further includes a second guard ring provided in the embedding layer near the dug section.

17. The light emitting device according to claim 1, wherein the element substrate and the driving circuit substrate further include, on the joint surface therebetween, a plurality of first pad electrodes and a plurality of second pad electrodes, the plurality of first pad electrodes electrically coupling the element substrate and the driving circuit substrate to each other, the plurality of second pad electrodes electrically floating.

18. The light emitting device according to claim 2, wherein
the element substrate and the driving circuit substrate further include, on the joint surface therebetween, a plurality of first pad electrodes electrically coupling the element substrate and the driving circuit substrate to each other, and
the first pad connection layer, the second pad connection layer, and the plurality of first pad electrodes are formed at positions that the first pad connection layer and the second pad connection layer do not overlap the plurality of first pad electrodes in plan view.

19. The light emitting device according to claim 9, wherein the element substrate further includes a protection film including inorganic material, the protection film covering side surfaces of the micro lens layer, the protection layer, the wavelength conversion layer, and the embedding layer.

20. An image display device, comprising
a light emitting device including
a driving circuit substrate,
an element substrate that has a first surface opposed to the driving circuit substrate and a second surface serving as a light exit surface on a side opposite to the first surface, that includes a pixel array section including a plurality of light emitting elements arranged in an array form, and that is joined to the driving circuit substrate through hybrid bonding, and
a mounting connection terminal and an external connection terminal that are electrically coupled to the driving circuit substrate outside the pixel array section and that are closer to the element substrate than a joint surface between the driving circuit substrate and the element substrate.
